(19) United States
(12) Patent Application Publication
(10) Pub. No.: US 2026/0096268 A1
(43) Pub. Date: Apr. 2, 2026

(54) DISPLAY APPARATUS AND ELECTRONIC DEVICE INCLUDING THE SAME

(71) Applicant: Samsung Display Co., Ltd., Yongin-si (KR)

(72) Inventors: Junhyeong Park, Yongin-si (KR); Junsu Park, Yongin-si (KR)

(21) Appl. No.: 19/326,656

(22) Filed: Sep. 11, 2025

(30) Foreign Application Priority Data
Sep. 30, 2024 (KR) 10-2024-0133253

(51) Int. Cl. H10H 29/49; H01L 25/16; H10H 29/01

(52) U.S. Cl. CPC H10H 29/49; H10H 29/012; H10W 90/00

(57) ABSTRACT

A display apparatus includes a light-emitting diode, a pixel circuit layer including a pixel circuit electrically connected to the light-emitting diode, and having a first pixel surface facing in a direction away from the light-emitting diode, a first connection line contacting the first pixel surface of the pixel circuit layer, and electrically connected to the pixel circuit, a terminal portion having a first terminal surface facing in the direction away from the light-emitting diode, a second connection line contacting the first pixel surface of the pixel circuit layer and the first terminal surface of the terminal portion, and electrically connecting the pixel circuit to the terminal portion, a printed circuit board including a driving circuit, and a connection portion electrically connecting the printed circuit board to the first terminal surface of the terminal portion.

### CROSS-REFERENCE TO RELATED APPLICATION

The present application claims priority to, and the benefit of, Korean Patent Application No. 10-2024-0133253, filed on Sep. 30, 2024, in the Korean Intellectual Property Office, the entire disclosure of which is incorporated herein by reference.

### BACKGROUND

### 1. Field

One or more embodiments relate to a display apparatus and an electronic device.

### 2. Description of the Related Art

Generally, according to the development of display panels visually displaying electrical signals, various display panels having excellent characteristics, such as reduction in thickness, light weight, and low power consumption, and electronic devices including the display panels have been introduced. For example, research and development have been actively conducted on display panels having various structures, such as flexible display panels that may be folded or rolled into a roll shape, stretchable display panels, and electronic devices including the display panels.

### SUMMARY

One or more embodiments include a display apparatus having improved stretchability and implementing images with excellent quality even when being stretched, and an electronic device including the display apparatus. However, these objectives are exemplary, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a light-emitting diode, a pixel circuit layer including a pixel circuit electrically connected to the light-emitting diode, and having a first pixel surface facing in a direction away from the light-emitting diode, a first connection line contacting the first pixel surface of the pixel circuit layer, and electrically connected to the pixel circuit, a terminal portion having a first terminal surface facing in the direction away from the light-emitting diode, a second connection line contacting the first pixel surface of the pixel circuit layer and the first terminal surface of the terminal portion, and electrically connecting the pixel circuit to the terminal portion, a printed circuit board including a driving circuit, and a connection portion electrically connecting the printed circuit board to the first terminal surface of the terminal portion.

The first pixel surface of the pixel circuit layer and the first terminal surface of the terminal portion may be at a same plane.

The display apparatus may further include a first elastomer layer below the first pixel surface of the pixel circuit layer and the first terminal surface of the terminal portion to overlap the first connection line and the second connection line.

The printed circuit board may contact the first elastomer layer.

The first elastomer layer may surround the connection portion in plan view.

The display apparatus may further include a second elastomer layer above the pixel circuit layer to cover the light-emitting diode.

The pixel circuit may include a semiconductor layer, and a gate electrode overlapping the semiconductor layer, and wherein the terminal portion includes a first terminal layer having the first terminal surface, and including a same material as the gate electrode.

The display apparatus may further include a signal line electrically connected to the pixel circuit, and contacting the first connection line.

The signal line may include a data line.

The first connection line and the second connection line may be stretchable.

According to one or more embodiments, an electronic device including a display panel having a terminal area, a pixel area, and a connection area, wherein the display panel includes a pixel circuit layer in the pixel area, and including a pixel circuit, a light-emitting diode above the pixel circuit layer, and electrically connected to the pixel circuit, a first connection line in the connection area, contacting a lower surface of the pixel circuit layer, and electrically connected to the pixel circuit, a terminal portion in the terminal area, a second connection line contacting the lower surface of the pixel circuit layer and a lower surface of the terminal portion, and electrically connecting the pixel circuit to the terminal portion, a printed circuit board including a driving circuit, and a connection portion electrically connecting the terminal portion to the printed circuit board.

The terminal area, the pixel area, and the connection area may be sequentially arranged in one direction.

The connection portion may contact the lower surface of the terminal portion and the lower surface of the pixel circuit layer.

The lower surface of the pixel circuit layer and the lower surface of the terminal portion may be at a same plane.

The display panel may further include a first elastomer layer below the lower surface of the terminal portion and the lower surface of the pixel circuit layer to overlap the first connection line and the second connection line.

The printed circuit board may contact the first elastomer layer.

The display panel may further include a second elastomer layer above the pixel circuit layer to cover the light-emitting diode.

The display panel may further include a signal line electrically connected to the pixel circuit and contacting the first connection line.

The signal line may include a data line.

The first connection line and the second connection line may be stretchable.

### BRIEF DESCRIPTION OF THE DRAWINGS

The above and other aspects of embodiments of the disclosure will be more apparent from the following description taken in conjunction with the accompanying drawings, in which:

FIG. 1A is a schematic perspective view of a display apparatus according to one or more embodiments;

FIG. 1B is a schematic block diagram of a display apparatus according to one or more embodiments;

FIG. 2 is a schematic perspective view of a display panel according to one or more embodiments;

FIGS. 3A and 3B are perspective views each illustrating a state in which the display panel of FIG. 2 is stretched in a first direction;

FIG. 3C is a perspective view illustrating a state in which the display panel of FIG. 2 is stretched in a second direction;

FIG. 3D is a perspective view illustrating a state in which the display panel of FIG. 2 is stretched in the first direction and the second direction;

FIG. 3E is a perspective view illustrating a state in which the display panel of FIG. 2 is stretched in a third direction;

FIG. 4 is a schematic plan view of a display panel according to one or more embodiments;

FIG. 5 is a plan view schematically illustrating an arrangement of pixels of a display panel according to one or more embodiments;

FIG. 6 is a schematic cross-sectional view of a portion of a display panel according to one or more embodiments;

FIGS. 7A to 7C are equivalent circuit diagrams each illustrating a pixel circuit of a display panel according to one or more embodiments;

FIGS. 8A to 8D are schematic cross-sectional views each illustrating a light-emitting diode of a display panel according to one or more embodiments;

FIGS. 9A to 9C are schematic cross-sectional views of a portion of a display panel according to one or more embodiments;

FIGS. 10A and 10B are schematic cross-sectional views of a portion of a terminal portion and a connection portion, according to one or more embodiments;

FIGS. 11A to 11K are cross-sectional views sequentially illustrating processes of a method of manufacturing a display panel according to one or more embodiments; and

FIGS. 12A to 12G are schematic perspective views respectively showing embodiments of an electronic device including a display panel according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

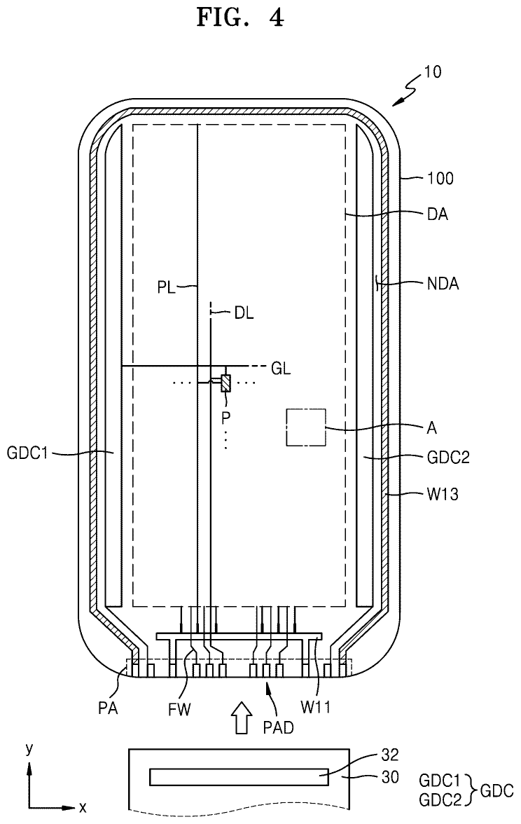

Further, the phrase “in a plan view” means when an object portion is viewed from above, and the phrase “in a schematic cross-sectional view” means when a schematic cross-section taken by vertically cutting an object portion is viewed from the side. In the disclosure, “in a plan view” means a plan view viewed in a direction perpendicular to a substrate 100 (refer to FIG. 4). That is, “A and B are spaced apart from each other in a plan view” means “A and B are spaced apart from each other when viewed in a direction perpendicular to the substrate 100 (refer to FIG. 4).”

The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B”may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),”etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure. ” Furthermore, the expression “being the same” may mean “being substantially the same”. In other words, the expression “being the same” may include a range that can be tolerated by those of ordinary skill in the art. The other expressions may also be expressions from which “substantially”has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

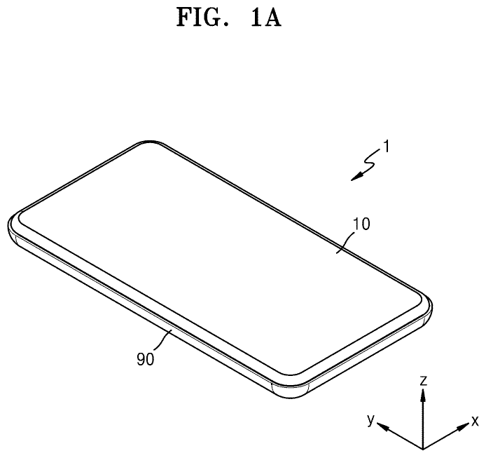

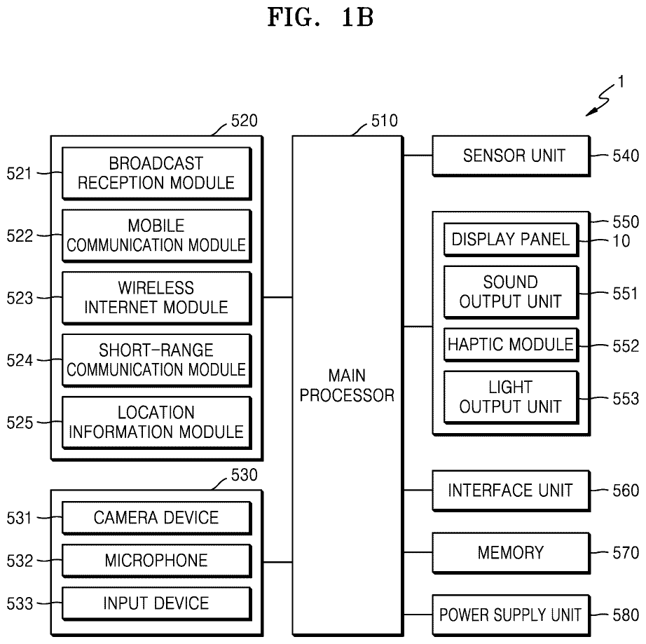

FIG. 1A is a schematic perspective view of a display apparatus 1 according to one or more embodiments, and FIG. 1B is a schematic block diagram of the display apparatus 1 according to one or more embodiments.

Referring to FIGS. 1A and 1B, the display apparatus 1 including a display panel 10 according to one or more embodiments is an apparatus displaying a video or a still image, and may be used as a display screen for various products, such as portable electronic devices including a mobile phone, a smart phone, a tablet personal computer (PC), a mobile communication terminal, an electronic notebook, an electronic book, a portable multimedia player (PMP), a navigation device, an ultra-mobile PC (UMPC), or the like, as well as a television, a laptop, a monitor, a billboard, and an Internet of Things (IoT) device. The display apparatus 1 according to one or more embodiments may be used as a wearable device, such as a smart watch, a watch phone, a glasses-type display, and a head-mounted display (HMD). The display apparatus 1 according to one or more embodiments may be used as a dashboard of a vehicle, a center fascia of a vehicle or a center information display (CID) arranged on a dashboard, a rear-view mirror display replacing a side mirror of a vehicle, and a display screen located on a back surface of a front seat as entertainment for a passenger in a back seat of a vehicle.

FIG. 1A shows that the display apparatus 1 according to one or more embodiments is a smart phone. The display apparatus 1 may include the display panel 10 and a lower cover 90 located on a lower portion of the display panel 10. The display apparatus 1 may include a cover window covering an upper surface of the display panel 10.

The lower cover 90 may form the exterior of the display apparatus 1, and may have an opening in a front surface thereof to expose a portion of the display panel 10. A surface of the lower cover 90, which corresponds to the display panel 10, has an open shape, and the lower cover 90 may be assembled with the display panel 10. The lower cover 90 forms the exterior of a lower surface of the display apparatus 1, and a printed circuit board, a component, a main circuit board, a battery, a driver, or the like may be located between the display panel 10 and the lower cover 90. The lower cover 90 may include plastic, metal, or both plastic and metal.

The display apparatus 1 may include a main processor 510, a wireless communication unit 520, an input unit 530, a sensor unit 540, an output unit 550, an interface unit 560, memory 570, and/or a power supply unit 580.

The main processor 510 may control all functions of the display apparatus 1. For example, the main processor 510 may output digital video data to a data driver via a printed circuit board so that the display panel 10 displays an image. The main processor 510 may receive sensing data from a touch sensor driving unit. The main processor 510 may determine whether a user has touched according to the sensing data and execute an operation corresponding to the user's direct touch or proximity touch. The main processor 510 may be an application processor including an integrated circuit, a central processing unit, or a system chip.

A camera device 531 processes an image frame, such as a still image, a video, or the like, obtained by an image sensor in a camera mode and outputs the processed image frame to the main processor 510. The camera device 531 may include at least one of a camera sensor (for example, a charge-coupled device (CCD), a complementary metal-oxide-semiconductor (CMOS), or the like), a photo sensor (or an image sensor), or a laser sensor. The camera device 531 may be connected to the image sensor and process an image input to the image sensor.

The wireless communication unit 520 may include at least one of a broadcast reception module 521, a mobile communication module 522, a wireless Internet module 523, a short-range communication module 524, or a location information module 525.

The broadcast reception module 521 may receive a broadcast signal and/or broadcast related information from an external broadcast management server through a broadcast channel. The broadcast channel may include a satellite channel and a terrestrial channel.

The mobile communication module 522 transmits and receives wireless signals to and from at least one of a base station, an external terminal, or a server on a communication network constructed according to technology standards or communication methods (for example, global system for mobile communication (GSM), code-division multi access (CDMA), code-division multi access 2000 (CDMA2000), evolution-data optimized or evolution-data only (EV-DO), wideband CDMA (WCDMA), high speed downlink packet access (HSDPA), high speed uplink packet access (HSUPA), long term evolution (LTE), long term evolution-advance (LTE-A), or the like) for mobile communication. The wireless signals may include various types of data according to transmission and reception of a voice call signal, a video call signal, or a text/multimedia message.

The wireless Internet module 523 refers to a module configured to perform wireless Internet access. The wireless Internet module 523 may be configured to transmit and receive wireless signals in a communication network according to wireless Internet technologies. Wireless Internet technologies include, for example, Wireless LAN (WLAN), Wireless-Fidelity (Wi-Fi®, Wi-Fi® being a registered trademark of the non-profit Wi-Fi Alliance), Wi-Fi Direct™ (Wi-Fi Direct™ being a registered trademark of the non-profit Wi-Fi Alliance), Digital Living Network Alliance (DLNA), or the like.

The short-range communication module 524 is a module configured to perform short-range communication, and may support short-range communication by using at least one of Bluetooth™ (Bluetooth™ being a registered trademark of Bluetooth Sig, Inc., Kirkland, WA), radio frequency identification (RFID), infrared data association (IrDA), ultra-wideband (UWB), ZigBee® (ZigBee® being a registered trademark of Connectivity Standards Alliance, CA), near-field communication (NFC), Wi-Fi®, Wi-Fi Direct™, or wireless universal serial bus (USB) technology. The short-range communication module 524 may support, through a wireless local area network, wireless communication between the display apparatus 1 and a wireless communication system, wireless communication between the display apparatus 1 and other electronic devices, or wireless communication between the display apparatus 1 and a network in which other electronic devices (or external servers) are located. The wireless local area network may be a wireless personal area network. The other electronic devices may be a wearable device capable of (or interoperable) of exchanging data with the display apparatus 1.

The location information module 525 is a module configured to obtain a location (or current location) of the display apparatus 1, and may include a global positioning system (GPS) module or a Wi-Fi® module.

The input unit 530 may include an image input unit, such as the camera device 531 configured to input an image signal, a sound input unit, such as a microphone 532 configured to input a sound signal, and an input device 533 configured to receive information from the user.

The camera device 531 processes an image frame, such as a still image or a video, obtained by an image sensor in a video call mode or a shooting mode. The processed image frame may be displayed on the display panel 10 or stored in the memory 570.

The microphone 532 processes external sound signals as electrical voice data. The processed voice data may be variously used according to a function (or an application being executed) that is being performed by the display apparatus 1.

The main processor 510 may control an operation of the display apparatus 1 to correspond to information input through the input device 533. The input device 533 may include a mechanical input unit or a touch input unit, such as a button, a dome switch, a jog wheel, a jog switch, or the like, located on a back surface or a side surface of the display apparatus 1. The touch input unit may be formed of a touch screen layer of the display panel 10.

The sensor unit 540 may include at least one sensor which senses at least one of information within the display apparatus 1, surrounding environment information surrounding the display apparatus 1, or user information, and generates a sensing signal corresponding to the at least one of the information within the display apparatus 1, the surrounding environment information surrounding the display apparatus 1, or the user information. The main processor 510 may, based on the sensing signal, control the driving or operation of the display apparatus 1, or perform data processing, function, or operation related to an application installed in the display apparatus 1. The sensor unit 540 may include at least one of a proximity sensor, an illumination sensor, an acceleration sensor, a magnetic sensor, a gravity sensor (G-sensor), a gyroscope sensor, a motion sensor, a red, green, blue (RGB) sensor, an infrared (IR) sensor, a finger scan sensor, an ultrasonic sensor, an optical sensor, a battery gauge, an environmental sensor (for example, a barometer, a hygrometer, a thermometer, a radioactive sensor, a thermal sensor, a gas sensor, or the like), or a chemical sensor (for example, an electronic nose, a health care sensor, a biometric sensor, or the like).

The output unit 550 is configured to generate output related to vision, hearing, sense of touch, or the like, and may include at least one of the display panel 10, a sound output unit 551, a haptic module 552, or a light output unit 553.

The display panel 10 displays (outputs) information processed by the display apparatus 1. For example, the display panel 10 may display execution screen information of an application driven by the display apparatus 1 or user interface (UI) or graphic user interface (GUI) information according to the execution screen information. The display panel 10 may include a display layer for displaying an image and a touch screen layer sensing a user's touch input. Therefore, the display panel 10 may function as one of the input devices 533 providing an input interface between the display apparatus 1 and the user and at the same time, may function as one of the output units 550 providing an output interface between the display apparatus 1 and the user.

The sound output unit 551 may output sound data received from the wireless communication unit 520 or stored in the memory 570 in a call reception mode, call mode or recording mode, voice recognition mode, broadcast reception mode, or the like. The sound output unit 551 may also output sound signals related to functions (for example, a call signal reception sound, a message reception sound, or the like) performed by the display apparatus 1. The sound output unit 551 may include a receiver and a speaker. At least one of the receiver and the speaker may be a sound generating device which is attached to a lower portion of the display panel 10 and vibrates the display panel 10 to output sound. The sound generating device may be a piezoelectric element or a piezoelectric actuator which contracts and expands according to an electrical signal, or may be an exciter that vibrates the display panel 10 by generating a magnetic force using a voice coil.

The haptic module 552 generates various effects of sense of touch that the user may feel. The haptic module 552 may provide vibration to the user as an effect of sense of touch. The haptic module 552 may not only deliver an effect of sense of touch through direct contact, but may also be implemented such that the user may feel an effect of sense of touch through muscle sensations, such as fingers or arms.

The light output unit 553 outputs a signal notifying the occurrence of an event by using light of a light source. Examples of events generated in the display apparatus 1 may include reception of messages, reception of call signals, missed calls, alarms, schedule notifications, reception of emails, reception of information through applications, or the like. The signal output by the light output unit 553 is implemented as the display apparatus 1 emits light of a single color or a plurality of colors to a front surface of a back surface thereof. The signal output may be terminated by the display apparatus 1 sensing the user's event confirmation.

The interface unit 560 serves as a passage with various types of external devices connected to the display apparatus 1. The interface unit 560 may include at least one of a wired/wireless headset port, an external charger port, a wired/wireless data port, a memory card port, a port connected to a device equipped with an identification module, an audio input/output (I/O) port, a video I/O port, or an earphone port. The display apparatus 1 may perform appropriate control related to a connected external device in response to the external device being connected to the interface unit 560.

The memory 570 stores data supporting various functions of the display apparatus 1. The memory 570 may store a plurality of application programs driven by the display apparatus 1, data and instructions for operations of the display apparatus 1. At least some of the plurality of application programs may be downloaded from external servers through wireless communication. The memory 570 may store an application for an operation of the main processor 510, and may also temporarily store input/output data, for example, data, such as a phone book, message, still image, video, or the like. In addition, the memory 570 may store haptic data for vibration of various patterns provided to the haptic module 552 and acoustic data related to various sounds provided to the sound output unit 551. The memory 570 may include a storage medium of at least one type of a flash memory type, a hard disk type, a solid state disk (SSD) type, a silicon disk drive (SDD) type, a multimedia card micro type, a card type memory (for example, a secure digital (SD) memory, an EXtreme digital (XD) memory, or the like), random access memory (RAM), static random access memory (SRAM), read-only memory (ROM), electrically erasable programmable read-only memory (EEPROM), programmable read-only memory (PROM), a magnetic memory, a magnetic disk, or an optical disk.

Under a control by the main processor 510, the power supply unit 580 receives external power and internal power to supply power to each component included in the display apparatus 1. The power supply unit 580 may include a battery. In addition, the power supply unit 580 may include a connection port, and the connection port may be configured as an example of the interface unit 560 to which an external charger that supplies power to charge the battery is electrically connected.

Alternatively, the power supply unit 580 may be configured to charge the battery wirelessly without using a connection port.

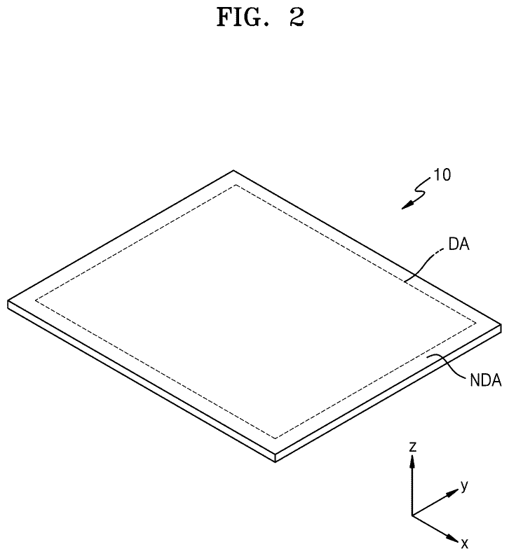

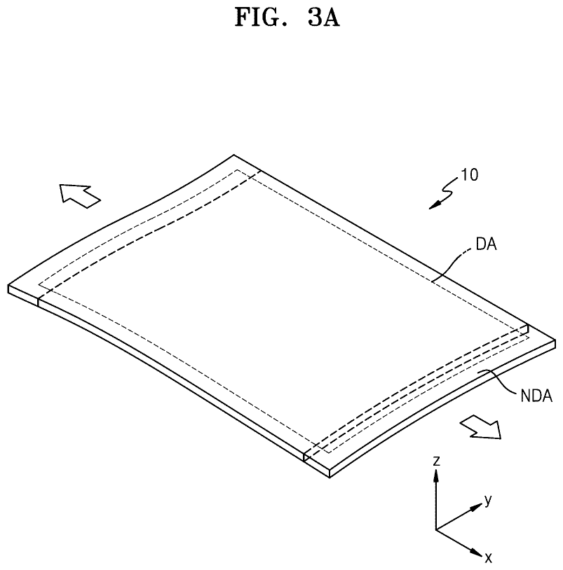

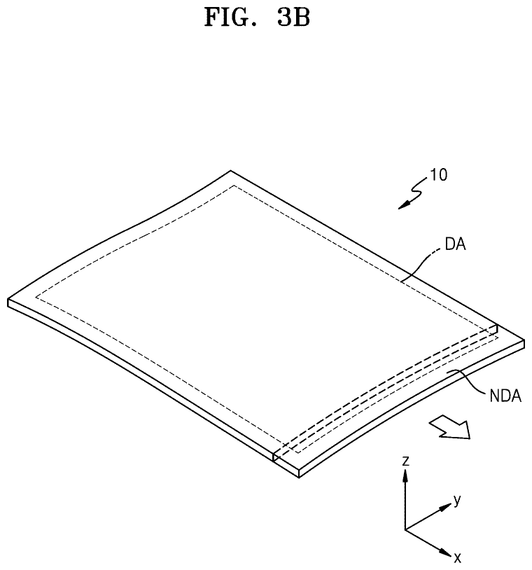

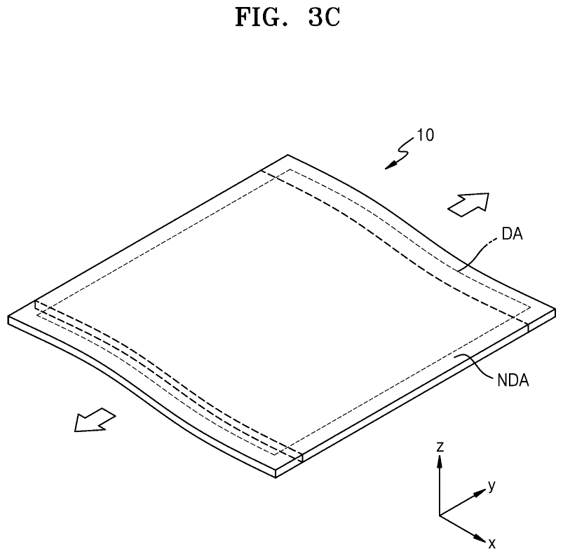

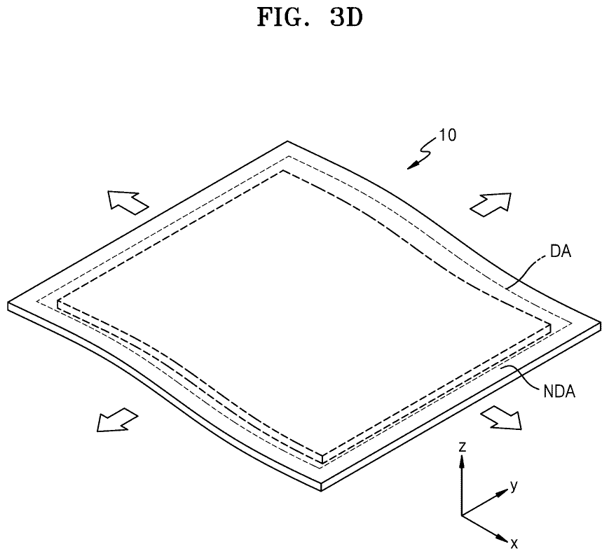

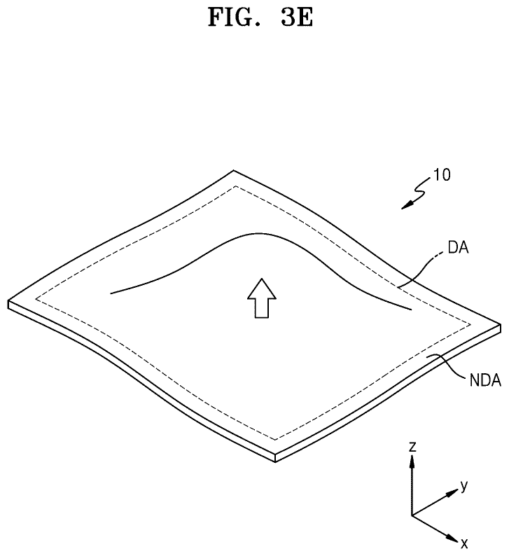

FIG. 2 is a schematic perspective view of the display panel 10 according to one or more embodiments. FIGS. 3A and 3B are perspective views each illustrating a state in which the display panel 10 of FIG. 2 is stretched in a first direction. FIG. 3C is a perspective view illustrating a state in which the display panel 10 of FIG. 2 is stretched in a second direction. FIG. 3D is a perspective view illustrating a state in which the display panel 10 of FIG. 2 is stretched in the first direction and the second direction. FIG. 3E is a perspective view illustrating a state in which the display panel 10 of FIG. 2 is stretched in a third direction.

Referring to FIG. 2, the display panel 10 may include a display area DA and a non-display area NDA. The display area DA may include a plurality of pixels. The display panel 10 may provide an image by using light emitted by the plurality of pixels. The non-display area NDA may be located outside the display area DA. The non-display area NDA may entirely surround the display area DA (e.g., in plan view).

The display panel 10 may be stretched or shrunk in various directions. The display panel 10 may be stretched in the first direction (e.g., an x direction and/or a −x direction) by an external force applied by an external object or the user. In one or more embodiments, as shown in FIGS. 3A and 3B, the display area DA and/or the non-display area NDA of the display panel 10 may be stretched in the first direction (e.g., the x direction and/or the −x direction). For example, as shown in FIG. 3A, the display panel 10 may be stretched in the x direction and the −x direction, or the display panel 10 may be stretched in the x direction in a state in which one side of the display panel 10 is fixed, as shown in FIG. 3B.

The display panel 10 may be stretched in the second direction (e.g., a y direction and/or a −y direction) by an external force applied by an external object or the user. In one or more embodiments, as shown in FIG. 3C, the display area DA and/or the non-display area NDA of the display panel 10 may be stretched in the y direction and the −y direction. In one or more other embodiments, the display panel 10 may be stretched in the y direction or the −y direction in a state in which one side of the display panel 10 is fixed.

The display panel 10 may be stretched in a plurality of directions, for example, the first direction (e.g., the x direction and/or the −x direction) and the second direction (e.g., the y direction and/or the −y direction), by an external force applied by an external object or a part of a human's body. As shown in FIG. 3D, the display area DA and/or the non-display area NDA of the display panel 10 may be stretched in the ±x direction and the ±y direction.

The display panel 10 may be stretched in the third direction (e.g., an z direction or a −z direction) by an external force applied by an external object or a part of a human's body. In one or more embodiments, FIG. 3E shows that a portion of the display panel 10, for example, a partial area of the display area DA, protrudes in the z direction. In one or more other embodiments, a portion of the display panel 10, for example, a partial area of the display area DA, may protrude in the z direction (or may be depressed in the −z direction).

FIGS. 3A to 3E show that the display apparatus 1 is stretched in the first direction, the second direction, and/or the third direction, but the disclosure is not limited thereto. In one or more other embodiments, the display panel 10 may be variously modified into irregular shapes, such as having two or more axes and being bent or twisted.

FIG. 4 is a schematic plan view of the display panel 10 according to one or more embodiments.

Referring to FIG. 4, the display panel 10 may include the display area DA and the non-display area NDA surrounding the display area DA. Pixels P are located in the display area DA of a substrate 100. The pixels P may respectively display images by using light emitted by respective light-emitting elements, such as light-emitting diodes. Each light-emitting diode may emit, for example, red, green, and blue light.

Each light-emitting diode may be electrically connected to a pixel circuit, and each pixel circuit may include transistors and a storage capacitor. Pixel circuits may be respectively electrically connected to peripheral circuits and peripheral lines located in the non-display area NDA. The peripheral circuits located in the non-display area NDA may include a gate-driving circuit GDC and a terminal portion PAD. The peripheral lines may include a driving voltage supply line W11, a common voltage supply line W13, and a fan-out line FW.

The gate-driving circuit GDC may include drivers configured to provide electrical signals to a gate electrode of each of the transistors electrically connected to light-emitting elements. For example, the gate-driving circuit GDC may respectively apply scan signals to pixel circuits corresponding to the pixels P through a gate line GL.

The gate-driving circuit GDC may include a first gate-driving circuit GDC1 and a second gate-driving circuit GDC2, which are located on both sides of the display panel 10 with the display area DA therebetween. The second gate-driving circuit GDC2 may be positioned on an opposite side of the first gate-driving circuit GDC1 with the display area DA therebetween, and may be substantially parallel with the first gate-driving circuit GDC1. Some of the pixel circuits may be electrically connected to the first gate-driving circuit GDC1, and the others thereof may be electrically connected to the second gate-driving circuit GDC2. In some embodiments, the second gate-driving circuit GDC2 may be omitted.

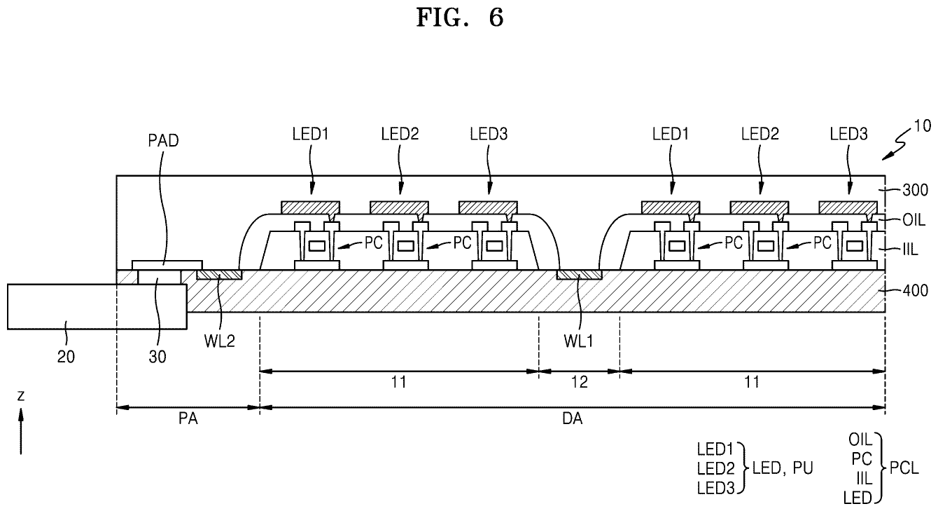

The non-display area NDA may include a terminal area PA in which the terminal portion PAD is located. The terminal area PA may be located on one side of the non-display area NDA. The terminal portion PAD may be located on one side of the substrate 100. The terminal portion PAD is exposed without being covered by an insulating layer to be connected to a printed circuit board 20 (refer to FIG. 6). A connection portion 30 may electrically connect the printed circuit board 20 to the terminal portion PAD. The printed circuit board 20 may include a driving circuit. A display driving unit 32 may be located in the printed circuit board 20. The display driving unit 32 may generate a control signal to be transmitted to the first gate-driving circuit GDC1 and the second gate-driving circuit GDC2. The display driving unit 32 may generate a data signal, and the generated data signal may be transmitted to pixel circuits of the pixels P through the fan-out line FW and a data line DL connected to the fan-out line FW.

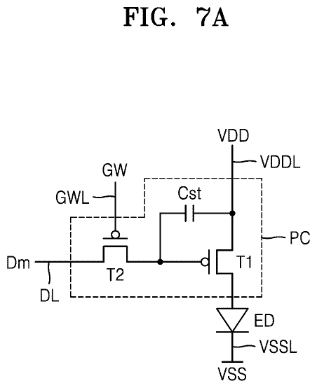

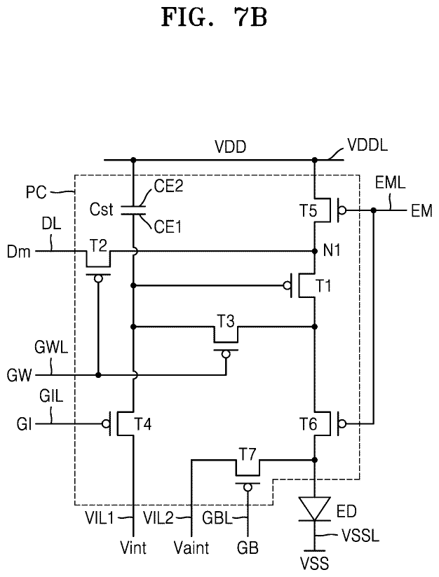

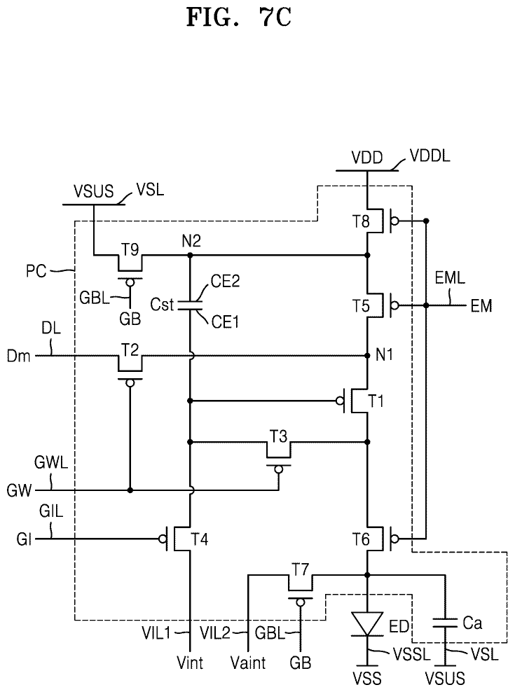

The display driving unit 32 may supply a first power voltage VDD (refer to FIG. 7A) to the driving voltage supply line W11 and supply a second power voltage VSS (refer to FIG. 7A) to the common voltage supply line W13. The first power voltage VDD (refer to FIG. 7A) may be applied to a pixel circuit of a pixel P through a driving voltage line PL connected to the driving voltage supply line W11, and the second power voltage VSS (refer to FIG. 7A) may be applied to an opposite electrode of a light-emitting element connected to the common voltage supply line W13. The driving voltage supply line W11 may be provided extending in an x direction from a lower side of the display area DA. The common voltage supply line W13 may have a loop shape with one side open to partially surround the display area DA.

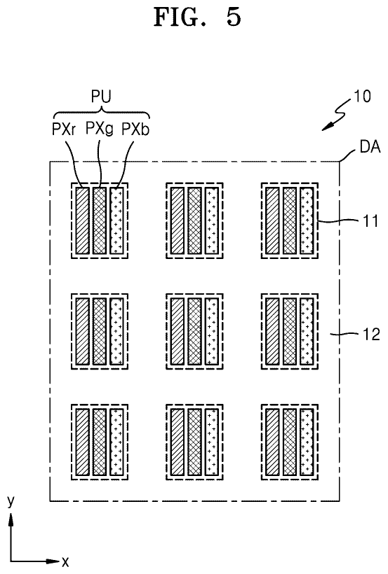

FIG. 5 is a plan view schematically illustrating an arrangement of pixels of a display panel according to one or more embodiments.

Referring to FIG. 5, a plurality of pixels (i.e., a red pixel PXr, a green pixel PXg, and a blue pixel PXb) may be located in the display area DA of the display panel 10. The display area DA may include a pixel area 11, and a connection area 12 outside the pixel area 11. The red pixel PXr, the green pixel PXg, and the blue pixel PXb may be located in the pixel area 11. The red pixel PXr, the green pixel PXg, and the blue pixel PXb may configure one pixel unit PU. Pixel units PU may be repeatedly arranged in the display area DA.

Signal lines electrically connected to adjacent pixels may be located in the connection area 12. The signal lines may be electrically connected to pixel circuits, and may be in contact with a first connection line WL1 (refer to FIG. 6). Each of the signal lines may include a first portion located in the pixel area 11 and electrically connected to the pixel circuit, and a second portion located in the connection area 12 and connecting adjacent pixel circuits to each other. At this time, the first portion and the second portion may include different materials. Hereinafter, in the disclosure, the second portion of each signal line may be referred to as a connection line.

The connection area 12 may be stretched relatively more than the pixel area 11 when the display panel 10 is stretched. In one or more embodiments, connection lines located in the connection area 12 may include a material having both excellent stretchability and electrical characteristics. For example, the connection lines located in the connection area 12 may include liquid metal or the like. Pixel areas 11 may be arranged at a corresponding distance in a first direction (e.g., an x direction) and a second direction (e.g., a y direction).

FIG. 6 is a schematic cross-sectional view of a portion of the display panel 10 according to one or more embodiments.

Referring to FIG. 6, the display area DA may include the pixel area 11 and the connection area 12, and the connection area 12 may be an area that connects adjacent pixel areas 11 to each other. The pixel area 11 may include a light-emitting diode LED, and a circuit for driving the light-emitting diode LED, for example, a pixel circuit PC. The first connection line WL1 electrically connecting adjacent pixel circuits PX to each other may be located in the connection area 12. The terminal area PA may be an area in which the terminal portion PAD is located. The terminal portion PAD, the pixel area 11, and the connection area 12 may be sequentially arranged in one direction. A second connection line WL2 electrically connecting the terminal portion PAD to the pixel circuit PC may be located in the terminal area PA.

The pixel area 11, the connection area 12, and the terminal area PA may be formed on a first elastomer layer 400. In other words, each of the pixel area 11, the connection area 12, and the terminal area PA may be defined in the first elastomer layer 400. The light-emitting diode LED and the pixel circuit PC may be located in the pixel area 11 of the first elastomer layer 400.

The first elastomer layer 400 may absorb stress that may occur when the display panel 10 is stretched. The first elastomer layer 400 may include an elastic polymer. For example, the first elastomer layer 400 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), or ECOFLEX™ (ECOFLEX™ being a registered trademark of PROFILE PRODUCTS LLC, Buffalo Grove, IL).

A pixel circuit layer PCL may be located in the pixel area 11 of the first elastomer layer 400. The pixel circuit layer PCL may include an inorganic insulating layer IIL, the pixel circuit PC, an organic insulating layer OIL, and the light-emitting diode LED. The pixel circuit PC may be located on the first elastomer layer 400, and the inorganic insulating layer IIL may be located between electrodes included in the pixel circuit PC. The organic insulating layer OIL may be located on the inorganic insulating layer IIL to cover the pixel circuit PC. The light-emitting diode LED may be located on the organic insulating layer OIL, and may be electrically connected to a corresponding pixel circuit PC. The inorganic insulating layer IIL may include an inorganic insulating material, such as silicon nitride and/or silicon oxide, and the organic insulating layer OIL may include an organic insulating layer, such as polyimide.

In one or more embodiments, one pixel unit PU may be located in one pixel area 11. The pixel unit PU may include the red pixel PXr (refer to FIG. 5), the green pixel PXg (refer to FIG. 5), and the blue pixel PXb (refer to FIG. 5), as described above. The red pixel PXr (refer to FIG. 5) may include a first light-emitting diode LED1, the green pixel PXg (refer to FIG. 5) may include a second light-emitting diode LED2, and the blue pixel PXb may include a third light-emitting diode LED3. For example, the first light-emitting diode LED1 may emit red light, the second light-emitting diode LED2 may emit green light, and the third light-emitting diode LED3 may emit blue light. In some embodiments, the light-emitting diode LED may also emit white light.

The first connection line WL1, which is stretchable, may be located in the connection area 12 of the first elastomer layer 400. The first connection line WL1 may be located within the first elastomer layer 400. The first connection line WL1 may include a material having both excellent stretchability and electrical characteristics. In one or more embodiments, the first connection line WL1 located in the connection area 12 may include liquid metal. In one or more other embodiments, the first connection line WL1 may include a metal nano structure and an elastic polymer. In one or more other embodiments, the first connection line WL1 may include a conductive composite material including an elastomer. In one or more embodiments, the second connection line WL2 may include the same material as the first connection line WL1. However, the disclosure is not limited thereto, and the second connection line WL2 may include a different material from that of the first connection line WL1.

The organic insulating layer OIL may be located in the connection area 12 of the first elastomer layer 400. In one or more embodiments, the organic insulating layer OIL located in the connection area 12 may be a portion of the organic insulating layer OIL located in the pixel area 11, which extends to the connection area 12. When the display panel 10 is stretched, the connection area 12 may be transformed relatively more as compared to the pixel area 11. Accordingly, unlike the pixel area 11, a layer including an inorganic insulating material, which is prone to cracking, may not exist in the connection area 12.

The terminal portion PAD and the second connection line WL2, which is stretchable, may be located in the terminal area PA of the first elastomer layer 400.

The terminal portion PAD may be located on the first elastomer layer 400. The second connection line WL2 may be located within the first elastomer layer 400. The second connection line WL2 may include a material having both excellent stretchability and electrical characteristics. In one or more embodiments, the second connection line WL2 located on the terminal area PA may include liquid metal. In one or more other embodiments, the second connection line WL2 may include a metal nano structure and an elastic polymer. In one or more other embodiments, the second connection line WL2 may include a conductive composite material including an elastomer.

In one or more embodiments, a second elastomer layer 300 may be located on the light-emitting diode LED and the terminal portion PAD. The second elastomer layer 300 may be located on a pixel circuit layer PCL to cover the light-emitting diode LED and the terminal portion PAD. The second elastomer layer 300 may be located in all of the pixel area 11, the connection area 12, and the terminal area PA. That is, the second elastomer layer 300 may entirely cover the display area DA and the terminal area PA. The second elastomer layer 300 may cover the light-emitting diode LED and the terminal portion PAD. The second elastomer layer 300 may absorb stress that may occur when the display panel 10 is stretched. For example, the second elastomer layer 300 may reduce or prevent stress that may occur when the display panel 10 is stretched from being transmitted to the light-emitting diode LED, the pixel circuit PC, and the terminal portion PAD.

The second elastomer layer 300 may include an elastic polymer. The second elastomer layer 300 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, PDMS, or ECOFLEX™ (ECOFLEX™ being a registered trademark of PROFILE PRODUCTS LLC, Buffalo Grove, IL). In one or more embodiments, the second elastomer layer 300 may include the same material as the first elastomer layer 400. However, the disclosure is not limited thereto, and the second elastomer layer 300 may include a different material from that of the first elastomer layer 400.

FIGS. 7A to 7C are equivalent circuit diagrams each illustrating a pixel circuit PC of a display panel according to one or more embodiments.

Referring to FIG. 7A, a light-emitting diode LED corresponding to a pixel may be electrically connected to the pixel circuit PC, and the pixel circuit PC may include a first transistor T1, a second transistor T2, and a storage capacitor Cst. The pixel circuit PC may be electrically connected to signal lines and voltage lines. The signal lines may include the gate line GL (refer to FIG. 4), such as a scan signal line GWL, and a data line DL, and the voltage lines may include a first voltage line VDDL. At this time, the first voltage line VDDL may be connected to the driving voltage supply line W11 (refer to FIG. 4), and a second voltage line VSSL may be connected to the common voltage supply line W13 (refer to FIG. 4).

The second transistor T2 may be electrically connected to the scan signal line GWL and the data line DL. The scan signal line GWL may provide a scan signal GW to a gate electrode of the second transistor T2. The second transistor T2 may be configured to transmit, to the first transistor T1, a data signal Dm input from the data line DL according to the scan signal GW input from the scan signal line GWL.

The storage capacitor Cst may be electrically connected to the second transistor T2 and the first voltage line VDDL, and may store a voltage corresponding to the difference between a voltage received from the second transistor T2 and a first power voltage VDD supplied by the first voltage line VDDL.

The first transistor T1 is a driving transistor, which may control a driving current flowing through the light-emitting diode LED. The first transistor T1 may be connected to the first voltage line VDDL and the storage capacitor Cst. The first transistor T1 may control the driving current flowing through the light-emitting diode LED from the first voltage line VDDL in accordance with a voltage value stored in the storage capacitor Cst. The light-emitting diode LED may emit light having a brightness corresponding to the driving current. A first electrode of the light-emitting diode LED may be electrically connected to the first transistor T1, and a second electrode thereof may be electrically connected to the second voltage line VSSL providing a second power voltage VSS.

FIG. 7A illustrates that the pixel circuit PC includes two transistors and one storage capacitor, but in one or more other embodiments, the pixel circuit PC may include three or more transistors.

Referring to FIG. 7B, the pixel circuit PC may include the first transistor T1, the second transistor T2, a third transistor T3, a fourth transistor T4, a fifth transistor T5, a sixth transistor T6, a seventh transistor T7, and the storage capacitor Cst.

The pixel circuit PC is electrically connected to signal lines and voltage lines. The signal lines may include the scan signal line GWL, a bypass control line GBL, an initialization control line GIL, the gate line GL (refer to FIG. 3), such as an emission control line EML, and the data line DL. The voltage lines may include first and second initialization voltage lines VIL1 and VIL2, and the first voltage line VDDL. At this time, the first voltage line VDDL may be connected to the driving voltage supply line W11 (refer to FIG. 3), and the second voltage line VSSL may be connected to the common voltage supply line W13 (refer to FIG. 3).

The first voltage line VDDL may be configured to transmit the first power voltage VDD to the first transistor T1. The first initialization voltage line VIL1 may be configured to transmit a first initialization voltage Vint for initializing the first transistor T1 to the pixel circuit PC. The second initialization voltage line VIL2 may be configured to transmit a second initialization voltage Vaint for initializing the first electrode of the light-emitting diode LED to the pixel circuit PC.

The first transistor T1 may be electrically connected to the first voltage line VDDL via the fifth transistor T5, and may be electrically connected to the light-emitting diode LED via the sixth transistor T6. The first transistor T1 serves as a driving transistor, and receives the data signal Dm according to a switching operation of the second transistor T2 to supply a driving current to the light-emitting diode LED.

The second transistor T2 is a data write transistor, which is electrically connected to the scan signal line GWL and the data line DL. The second transistor T2 is electrically connected to the first voltage line VDDL via the fifth transistor T5. The second transistor T2 is turned on in response to the scan signal GW received through the scan signal line GWL, and performs a switching operation of providing the data signal Dm transmitted with the data line DL to a first node N1.

The third transistor T3 is electrically connected to the scan signal line GWL, and is electrically connected to the light-emitting diode LED via the sixth transistor T6. The third transistor T3 may be turned on in response to the scan signal GW received through the scan signal line GWL to diode-connect the first transistor T1.

The fourth transistor T4 is a first initialization transistor, which is electrically connected to the initialization control line GIL and to the first initialization voltage line VIL1. The fourth transistor T4 is turned on in response to an initialization control signal GI received through the initialization control line GIL to transmit the first initialization voltage Vint from the first initialization voltage line VIL1 to a gate electrode of the first transistor T1 to initialize the gate electrode of the first transistor T1. The initialization control signal GI may correspond to a scan signal from another pixel circuit located in a previous row of the corresponding pixel circuit PC.

The fifth transistor T5 may be an operation control transistor, and the sixth transistor T6 may be an emission control transistor. The fifth transistor T5 and the sixth transistor T6 are electrically connected to the emission control line EML and are concurrently or substantially simultaneously turned on in response to an emission control signal EM received through the emission control line EML to form a current path so that a driving current may flow in a direction from the first voltage line VDDL to the light-emitting diode LED.

The seventh transistor T7 is a second initialization transistor, which may be electrically connected to the bypass control line GBL, to the second initialization voltage line VIL2, and to the sixth transistor T6. The seventh transistor T7 may be turned on in response to a bypass control signal GB received through the bypass control line GBL, and may transmit the second initialization voltage Vaint from the second initialization voltage line VIL2 to the first electrode of the light-emitting diode LED to initialize the first electrode of the light-emitting diode LED.

The storage capacitor Cst may include a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to the difference between voltages of both ends of the first voltage line VDDL and the gate electrode of the first transistor T1.

Referring to FIG. 7C, the pixel circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel circuit PC is electrically connected to signal lines and voltage lines. The signal lines may include the scan signal line GWL, the bypass control line GBL, the initialization control line GIL, a gate line, such as the emission control line EML, and the data line DL. The voltage lines may include the first and second initialization voltage lines VIL1 and VIL2, a maintenance voltage line VSL, and the first voltage line VDDL. At this time, the first voltage line VDDL may be connected to the driving voltage supply line W11 (refer to FIG. 4), and the second voltage line VSSL may be connected to the common voltage supply line W13 (refer to FIG. 4).

The first voltage line VDDL may be configured to transmit the first power voltage VDD to the first transistor T1. The first initialization voltage line VIL1 may be configured to transmit the first initialization voltage Vint initializing the first transistor T1 to the pixel circuit PC. The second initialization voltage line VIL2 may be configured to transmit the second initialization voltage Vaint initializing the first electrode of the light-emitting diode LED to the pixel circuit PC. The maintenance voltage line VSL may provide a maintenance voltage VSUS to a second node N2, for example, the second electrode CE2 of the storage capacitor Cst, during an initialization section and a data write section.

The first transistor T1 may be electrically connected to the first voltage line VDDL via the fifth transistor T5 and the eighth transistor T8, and may be electrically connected to the light-emitting diode LED via the sixth transistor T6. The first transistor T1 serves as a driving transistor, and receives the data signal Dm according to a switching operation of the second transistor T2 to supply a driving current to the light-emitting diode LED.

The second transistor T2 is electrically connected to the scan signal line GWL and the data line DL, and is electrically connected to the first voltage line VDDL via the fifth transistor T5 and the eighth transistor T8. The second transistor T2 is turned on in response to the scan signal GW received through the scan signal line GWL, and performs a switching operation of transmitting the data signal Dm transmitted through the data line DL to the first node N1.

The third transistor T3 is electrically connected to the scan signal line GWL, and is electrically connected to the light-emitting diode LED via the sixth transistor T6. The third transistor T3 may be turned on in response to the scan signal GW received through the scan signal line GWL to diode-connect the first transistor T1, thereby compensating for a threshold voltage of the first transistor T1.

The fourth transistor T4 is electrically connected to the initialization control line GIL and to the first initialization voltage line VIL1, and is turned on in response to the initialization control signal GI received through the initialization control line GIL to transmit the first initialization voltage Vint from the first initialization voltage line VIL1 to the gate electrode of the first transistor T1 to initialize the voltage of the gate electrode of the first transistor T1. The initialization control signal GI may correspond to a scan signal from another pixel circuit located in a previous row of the corresponding pixel circuit PC.

The fifth transistor T5, the sixth transistor T6, and the eighth transistor T8 are electrically connected to the emission control line EML, and are concurrently or substantially simultaneously turned on in response to the emission control signal EM received through the emission control line EML to form a current path so that a driving current may flow in a direction from the first voltage line VDDL to the light-emitting diode LED.

The seventh transistor T7 is a second initialization transistor, which may be electrically connected to the bypass control line GBL, to the second initialization voltage line VIL2, and to the sixth transistor T6. The seventh transistor T7 is turned on in response to the bypass control signal GB received through the bypass control line GBL, and transmits the second initialization voltage Vaint from the second initialization voltage line VIL2 to the first electrode of the light-emitting diode LED to initialize the first electrode of the light-emitting diode LED.

The ninth transistor T9 may be electrically connected to the bypass control line GBL, to the second electrode CE2 of the storage capacitor Cst, and to the maintenance voltage line VSL. The ninth transistor T9 may be turned on in response to the bypass control signal GB received through the bypass control line GBL, and may transmit the maintenance voltage VSUS to the second node N2, for example, to the second electrode CE2 of the storage capacitor Cst, during an initialization section and a data write section.

Each of the eighth transistor T8 and the ninth transistor T9 may be electrically connected to the second node N2, for example, to the second electrode CE2 of the storage capacitor Cst. In some embodiments, the eighth transistor T8 may be turned off and the ninth transistor T9 may be turned on during the initialization section and the data write section, and the eighth transistor T8 may be turned on and the ninth transistor T9 may be turned off during an emission section. Because the maintenance voltage VSUS is transmitted to the second node N2 during the initialization section and the data write section, the brightness uniformity (for example, long-range uniformity (LRU)) of a display apparatus according to a voltage drop of the first voltage line VDDL may be improved.

The storage capacitor Cst may include the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, to the maintenance voltage line VSL, and to the first electrode of the light-emitting diode LED. The auxiliary capacitor Ca may store and maintain a voltage corresponding to the voltage difference between the first electrode of the light-emitting diode LED and the maintenance voltage line VSL while the seventh transistor T7 and the ninth transistor T9 are turned on, so that a problem in which black brightness increases when the sixth transistor T6 is turned off may be reduced or prevented.

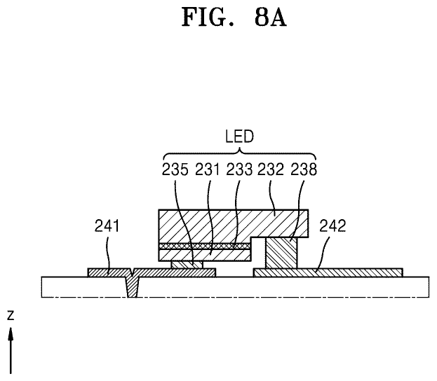

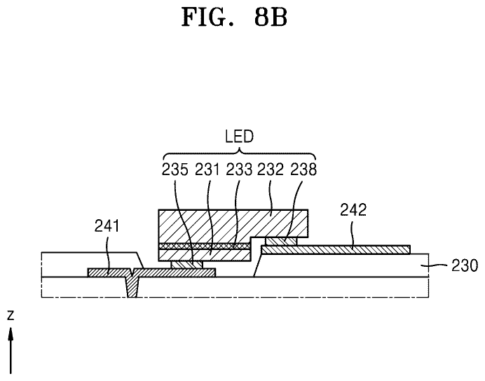

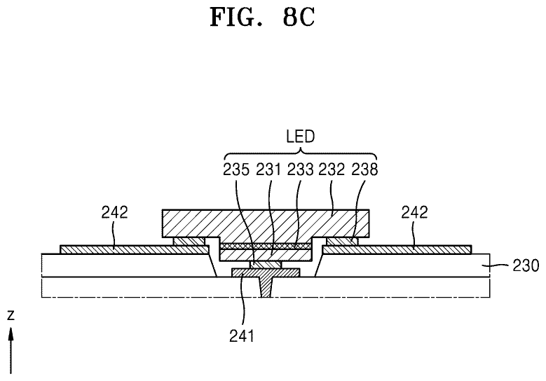

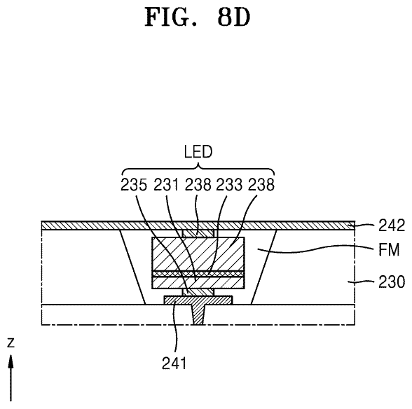

FIGS. 8A to 8D are schematic cross-sectional views each illustrating a light-emitting diode LED of a display panel according to one or more embodiments.

Referring to FIG. 8A, the light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may respectively be electrically connected to a first electrode pad 241 and a second electrode pad 242, which are located on a same layer as each other. The second electrode pad 242 may be a portion of the second voltage line VSSL (refer to FIG. 7A), or may be a conductive layer electrically connected to the second voltage line VSSL.

In some embodiments, the first semiconductor layer 231 may include a p-type semiconductor layer. The p-type semiconductor layer is a semiconductor material with a composition formula of InₓAl_{y}Ga_{1-x-y}N (0≤x≤1, 0≤y≤1, 0≤x+y≤1), which may, for example, be selected from among GaN, AlN, AlGaN, InGaN, InN, InAlGaN, AlInN, or the like, and may be doped with a p-type dopant, such as Mg, Zn, Ca, Sr, Ba, or the like.

The second semiconductor layer 232 may include, for example, an n-type semiconductor layer. The n-type semiconductor layer is a semiconductor material having a composition formula of InₓAl_{y}Ga_{1-x-y}N (0≤x≤1, 0≤y≤1, 0≤x+y≤1), which may, for example, be selected from among GaN, AlN, AlGaN, InGaN, InN, InAlGaN, AlInN, or the like, and may be doped with an n-type dopant, such as Si, Ge, Sn, or the like.

The intermediate layer 233 is a region where electrons and holes are recombined. As the electrons and holes are recombined, the intermediate layer 233 may transition to a low energy level and generate light having a corresponding wavelength. For example, the intermediate layer 233 may be formed by including a semiconductor material having a composition formula of InₓAl_{y}Ga_{1-x-y}N (0≤x≤1, 0≤y≤1, 0≤x+y≤1), and may be formed as a single-quantum well structure or a multi-quantum well (MQW) structure. In addition, the intermediate layer 233 may also include a quantum wire structure or a quantum dot structure.

FIG. 8A illustrates that the first semiconductor layer 231 includes a p-type semiconductor layer, and the second semiconductor layer 232 includes an n-type semiconductor layer, but the disclosure is not limited thereto. In one or more other embodiments, the first semiconductor layer 231 may include an n-type semiconductor layer, and the second semiconductor layer 232 may include a p-type semiconductor layer.

FIG. 8A illustrates that the first electrode pad 241 and the second electrode pad 242 are located on the same layer, but the disclosure is not limited thereto. Referring to FIG. 8B, the first electrode pad 241 and the second electrode pad 242 may be located on different respective layers. For example, a bank layer 230 having an opening overlapping at least a portion of the first electrode pad 241 may be located on the first electrode pad 241, and the second electrode pad 242 may be located on an upper surface of the bank layer 230. A structure of the light-emitting diode LED shown in FIG. 8B is the same as that described above with reference to FIG. 8A.

In one or more other embodiments, as shown in FIG. 8C, the second electrode pad 242 may be located on each of both sides of the first electrode pad 241 in a cross-sectional view. The bank layer 230 may include an opening overlapping at least a portion of the first electrode pad 241, and the second electrode pad 242 may be located around the opening of the bank layer 230. In some embodiments, in a plan view, the second electrode pad 242 may have a closed loop shape that entirely surrounds the opening of the bank layer 230 and/or the first electrode pad 241 (e.g., in plan view). A structure of the light-emitting diode LED shown in FIG. 8C is the same as that described above with reference to FIG. 8A.

FIGS. 8A to 8C illustrate that the first electrode 235 and the second electrode 238 of the light-emitting diode LED face the same direction (e.g., a downward direction and a-z direction), but the disclosure is not limited thereto. As shown in FIG. 8D, the first electrode 235 and the second electrode 238 of the light-emitting diode LED may face opposite directions.

The bank layer 230 may include an opening exposing at least a portion of the first electrode pad 241, and a thickness of the bank layer 230 may be substantially equal to a thickness of the light-emitting diode LED. The opening of the bank layer 230 may be filled with a filling material FM, and the second electrode pad 242 may be located on an upper surface of the bank layer 230 to be electrically connected (e.g., in contact with) to the second electrode 238 of the light-emitting diode LED. The filling material FM may be an insulating organic material.

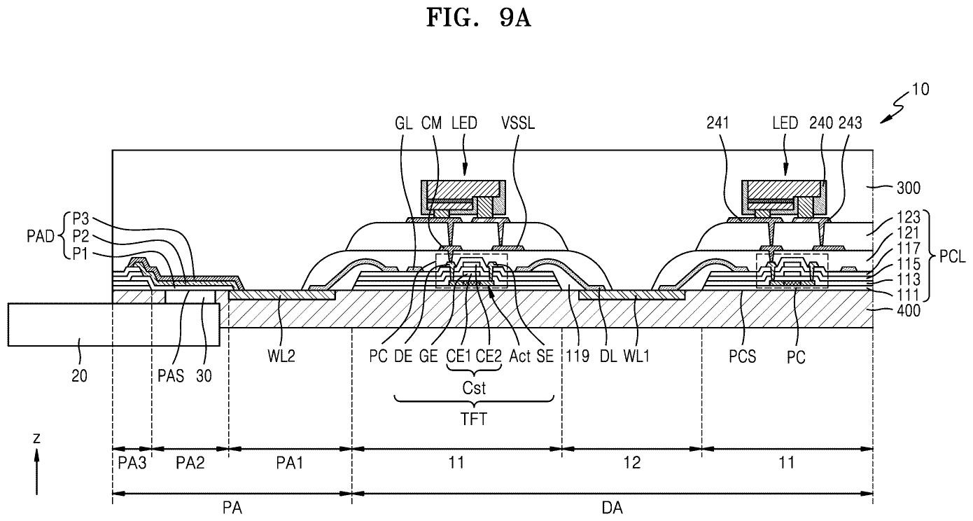

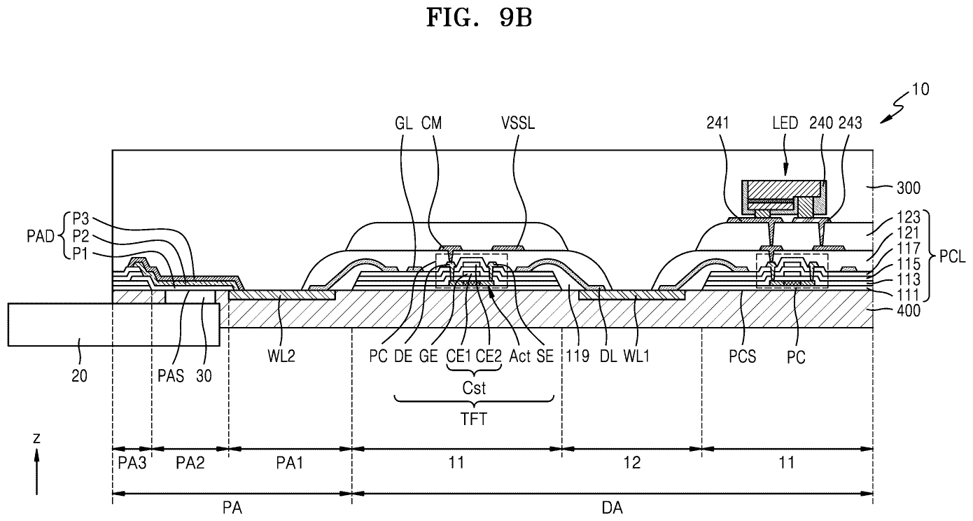

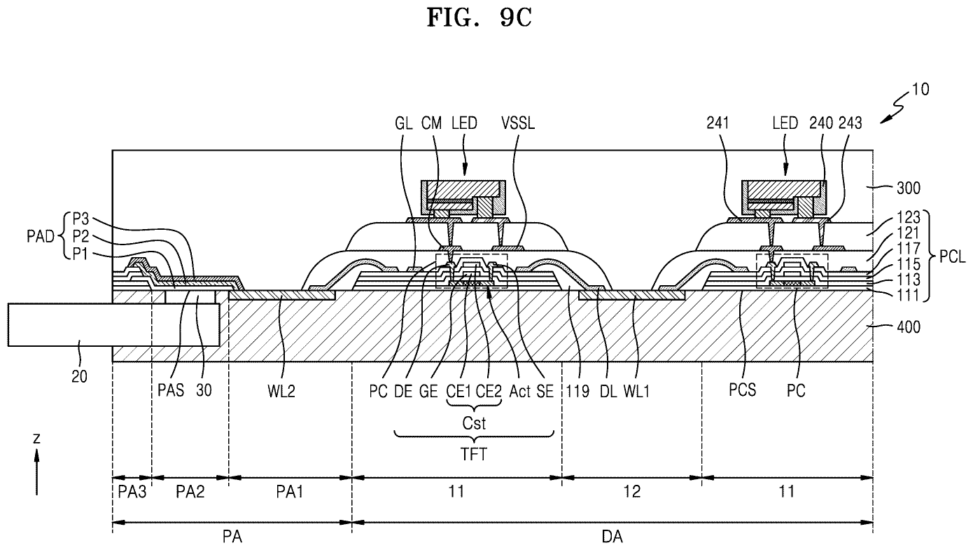

FIGS. 9A to 9C are schematic cross-sectional views of a portion of the display panel 10 according to one or more embodiments.

Referring to FIGS. 9A to 9C, the display panel 10 may include the first elastomer layer 400. The first elastomer layer 400 may absorb stress that may occur when the display panel 10 is stretched, as described above. The first elastomer layer 400 may include the same material as that described above with reference to FIG. 6.

The pixel areas 11, the connection area 12 between the pixel areas 11, and the terminal area PA may be defined in the display panel 10. A pixel circuit layer PCL including the pixel circuit PC and the light-emitting diode LED located on the pixel circuit layer PCL may be located in the pixel area 11 of the first elastomer layer 400.

A buffer layer 111 may be located on the first elastomer layer 400, and the pixel circuit PC may be located on the buffer layer 111 (as used herein, “located on” may mean “above”). The buffer layer 111 may include an inorganic insulating material, such as silicon oxide, silicon nitride, and/or silicon oxynitride.

A thin-film transistor TFT may include a semiconductor layer Act, a gate electrode GE, a source electrode SE, and a drain electrode DE. FIG. 9A illustrates a top-gate type in which the gate electrode GE is located on the semiconductor layer Act with a gate-insulating layer 113 therebetween, but according to one or more other embodiments, the thin-film transistor TFT may be a bottom-gate type.

The semiconductor layer Act may include polysilicon. Alternatively, the semiconductor layer Act may include amorphous silicon, an oxide semiconductor, an organic semiconductor, or the like. The gate electrode GE may overlap the semiconductor layer Act. The gate electrode GE may include a metal thin film including a low-resistance metal material. The gate electrode GE may include a conductive material including molybdenum (Mo), aluminum (Al), copper (Cu), titanium (Ti), or the like, and may be a multi-layer or a single layer, each including the material stated above. For example, the gate electrode GE may include a metal thin film including a triple layer of a Ti/Al/Ti structure.

The gate-insulating layer 113 between the semiconductor layer Act and the gate electrode GE may include an inorganic insulating material, such as silicon oxide, silicon nitride, silicon oxynitride, aluminum oxide, and/or titanium oxide. The gate-insulating layer 113 may be a single layer or a multi-layer, each including the material described above.

The source electrode SE and the drain electrode DE may be positioned on the same layer, for example, on a second interlayer insulating layer 117, and may include the same material. The source electrode SE and the drain electrode DE may each include a metal thin film including a low-resistance metal material. Each of the source electrode SE and the drain electrode DE may include a conductive material including Mo, Al, Cu, Ti, or the like, and may include a multi-layer or a single layer, each including the above material. For example, similar to the gate electrode GE, each of the source electrode SE and the drain electrode DE may include a metal thin film including a triple layer of a Ti/Al/Ti structure. The second interlayer insulating layer 117 may include an inorganic insulating material, such as silicon oxide, silicon nitride, silicon oxynitride, aluminum oxide, and titanium oxide, and may be a single layer or a multi-layer, each including the material described above.

The storage capacitor Cst may include the first electrode CE1 and the second electrode CE2, which overlap each other with a first interlayer insulating layer 115 therebetween. The storage capacitor Cst may overlap the thin-film transistor TFT. In this regard, FIG. 9A illustrates that the gate electrode GE of the thin-film transistor TFT is the first electrode CE1 of the storage capacitor Cst. In one or more other embodiments, the storage capacitor Cst may not overlap the thin-film transistor TFT.

The storage capacitor Cst may be covered by the second interlayer insulating layer 117.

The first interlayer insulating layer 115 may be located between the gate-insulating layer 113 and the second interlayer insulating layer 117. The first interlayer insulating layer 115 may include an inorganic insulating material, such as silicon oxide, silicon nitride, silicon oxynitride, aluminum oxide, and titanium oxide, and may be a single layer or a multi-layer, each including the material described above.

The second electrode CE2 of the storage capacitor Cst may include a conductive material, and may be formed as a multi-layer or a single layer. The second electrode CE2 may include a metal thin film including a low-resistance metal material. The second electrode CE2 may include a conductive material including Mo, Al, Cu, Ti, or the like, and may be formed as a multi-layer or a single layer, each including the above material. For example, the second electrode CE2 may include a metal thin film including a triple layer of a Ti/Al/Ti structure.

As shown in FIG. 9B, the thin-film transistor TFT may include the first transistor T1 (refer to FIG. 7A) and the second transistor T2 (refer to FIG. 7A). Among two thin-film transistors TFT shown in FIG. 9B, a thin-film transistor located to be further away from the terminal portion PAD may be identified as the first transistor T1 (refer to FIG. 7A). In addition, among the two thin-film transistors TFT shown in FIG. 9B, a thin-film transistor located to be adjacent to the terminal portion PAD may be identified as the second transistor T2 (refer to FIG. 7A). The first transistor T1 (refer to FIG. 7A) may perform a driving transistor function as described above with reference to FIG. 7A. In addition, the second transistor T2 (refer to FIG. 7A) may be electrically connected to a signal line, and may be configured to transmit a signal input from the signal line to the first transistor T1 (refer to FIG. 7A).

A first organic insulating layer 121 may be located on the second interlayer insulating layer 117, and a second organic insulating layer 123 may be located on the first organic insulating layer 121. In addition, a sub-organic insulating layer 119 may be arranged between the second interlayer insulating layer 117 and the first organic insulating layer 121 at an outer area of the pixel area 11 adjacent to the connection area 12. Each of the sub-organic insulating layer 119, the first organic insulating layer 121, and the second organic insulating layer 123 may include an organic insulating material, such as polyimide.

The inorganic insulating layer IIL (refer to FIG. 6) including the buffer layer 111, the gate-insulating layer 113, the first interlayer insulating layer 115, and the second interlayer insulating layer 117 may be located only in the pixel area 11, and may not be located in the connection area 12. In other words, a partial area of the inorganic insulating layer IIL (refer to FIG. 6), which overlaps the connection area 12, may be removed. At this time, a step-difference that may occur between the pixel area 11 and the connection area 12 may be filled with the sub-organic insulating layer 119. The second organic insulating layer 123 may extend in the pixel area 11 to be partially located in the connection area 12.

The gate line GL and the data line DL may be located on the second interlayer insulating layer 117, and the first organic insulating layer 121 may be located on the gate line GL and the data line DL. In one or more embodiments, a portion of the data line DL located in the pixel area 11 may extend to the connection area 12 to be in direct contact with the first connection line WL1. The portion of the data line DL, which extends to the connection area 12, may be located on the sub-organic insulating layer 119. In one or more embodiments, an end of the portion of the data line DL, which extends to the connection area 12, may be in direct contact with the first connection line WL1. In one or more embodiments, a portion of the data line DL located in the pixel area 11 may extend to the terminal area PA to be in direct contact with the second connection line WL2. The portion of the data line DL, which extends to the terminal area PA, may be located on the sub-organic insulating layer 119. In one or more embodiments, an end of the portion of the data line DL, which extends to the terminal area PA, may be in direct contact with the second connection line WL2. The first organic insulating layer 121 may cover the data line DL. The first organic insulating layer 121 may cover at least a portion of the first connection line WL1. The first organic insulating layer 121 may cover at least a portion of the second connection line WL2. Because the data line DL is covered by the first organic insulating layer 121, the data line DL may be protected by the first organic insulating layer 121 during an etching operation.

A connection electrode CM and the second voltage line VSSL may be located on the first organic insulating layer 121. The connection electrode CM may electrically connect the thin-film transistor TFT to the light-emitting diode LED. The second voltage line VSSL may be connected to the common voltage supply line W13 (refer to FIG. 4), and may be configured to transmit the second power voltage VSS (refer to FIG. 7A) to the second electrode 238 (refer to FIG. 8A). Each of the connection electrode CM and the second voltage line VSSL may include a metal thin film including a low-resistance metal material. Each of the connection electrode CM and the second voltage line VSSL may include a conductive material including Mo, Al, Cu, Ti, or the like, and may include a multi-layer or a single layer, each including the above material. For example, each of the connection electrode CM and the second voltage line VSSL may include a metal thin film including a triple layer of a Ti/Al/Ti structure.

The first electrode pad 241 and the second electrode pad 242 may be located on the second organic insulating layer 123. The first electrode pad 241 may be electrically connected to the thin-film transistor TFT through the connection electrode CM between the first organic insulating layer 121 and the second organic insulating layer 123. The light-emitting diode LED on the first electrode pad 241 and the second electrode pad 242 may be the same as the inorganic light-emitting diode described above with reference to FIG. 8B. The light-emitting diode LED, which is an inorganic light-emitting diode, may include the first semiconductor layer 231 (refer to FIG. 8B), the second semiconductor layer 232 (refer to FIG. 8B), the intermediate layer 233 (refer to FIG. 8B) between the first semiconductor layer 231 (refer to FIG. 8B) and the second semiconductor layer 232 (refer to FIG. 8B), a first electrode 235 (refer to FIG. 8B) electrically connected to the first semiconductor layer 231 (refer to FIG. 8B), and a second electrode 238 (refer to FIG. 8B) electrically connected to the second semiconductor layer 232 (refer to FIG. 8B). The light-emitting diode LED may be covered with a protective layer 240. The protective layer 240 may include an organic insulating material, such as polyimide.

The terminal area PA may include a first terminal area PA1, a second terminal area PA2, and a third terminal area PA3. The first terminal area PA1, the second terminal area PA2, and the third terminal area PA3 may be sequentially located in a direction away from the display area DA. The second terminal area PA2 may be located between the first terminal area PA1 and the third terminal area PA3. That is, the third terminal area PA3, the second terminal area PA2, the first terminal area PA1, the pixel area 11, and the connection area 12 may be sequentially located in one direction.

The terminal portion PAD may be located on the second terminal area PA2 of the first elastomer layer 400. The terminal portion PAD may include a first terminal layer P1, a second terminal layer P2, and a third terminal layer P3. The first terminal layer P1 may be located at a lower portion of the terminal portion PAD. A lower surface of the terminal portion PAD is referred to as a first terminal surface PAS. That is, the terminal portion PAD may have the first terminal surface PAS facing a direction away from the light-emitting diode LED. A lower surface of the first terminal layer P1 may form the lower surface of the terminal portion PAD. That is, the first terminal layer P1 may have the first terminal surface PAS.

The first terminal layer P1 may include the same material as the gate electrode GE. The first terminal layer P1 may be formed by the same process as the gate electrode GE. The first terminal layer P1 may include a conductive material including Mo, Al, Cu, Ti, or the like, and may be formed as a multi-layer or a single layer, each including the above material. For example, the first terminal layer P1 may include a metal thin film including a triple layer of a Ti/Al/Ti structure.

The second terminal layer P2 may be located on the first terminal layer P1. The second terminal layer P2 may be electrically connected to the first terminal layer P1. The second terminal layer P2 may be in direct contact with the first terminal layer P1. The second terminal layer P2 may include the same material as the source electrode SE and/or the drain electrode DE. The second terminal layer P2 may be formed by the same process as the source electrode SE and/or the drain electrode DE. The second terminal layer P2 may include a thin metal film including a low-resistance metal material. The second terminal layer P2 may include a conductive material including Mo, Al, Cu, Ti, or the like, and may be formed as a multi-layer or a single layer, each including the above material. For example, the second terminal layer P2 may include a metal thin film including a triple layer of a Ti/Al/Ti structure.

The third terminal layer P3 may be located on the second terminal layer P2. The third terminal layer P3 may be electrically connected to the second terminal layer P2. The third terminal layer P3 may be in direct contact with the second terminal layer P2. The third terminal layer P3 may include the same material as the connection electrode CM. The third terminal layer P3 may be formed by the same process as the connection electrode CM. The third terminal layer P3 may include a metal thin film including a low-resistance metal material. The third terminal layer P3 may include a conductive material including Mo, Al, Cu, Ti, or the like, and may be formed as a multi-layer or a single layer, each including the above material. For example, the third terminal layer P3 may include a metal thin film including a triple layer of a Ti/Al/Ti structure.

The inorganic insulating layer IIL (refer to FIG. 6) may be located on the third terminal area PA3 of the first elastomer layer 400. The buffer layer 111 located on the first elastomer layer 400, the gate-insulating layer 113 located on the buffer layer 111, the first interlayer insulating layer 115 located on the gate-insulating layer 113, and the second interlayer insulating layer 117 located on the first interlayer insulating layer 115 may be located in the third terminal area PA3.

In the third terminal area PA3, the first terminal layer P1 may be arranged between the gate-insulating layer 113 and the first interlayer insulating layer 115. The first interlayer insulating layer 115 may cover an end portion of the first terminal layer P1. In the third terminal area PA3, the second terminal layer P2 may be located on the second interlayer insulating layer 117. In the third terminal area PA3, the third terminal layer P3 may be located on the second terminal layer P2. An end portion of each of the first terminal layer P1, the second terminal layer P2, and the third terminal layer P3 may be located in the third terminal area PA3.

The first connection line WL1 electrically connected to the pixel circuit PC may be located in the connection area 12 of the display panel 10. The first connection line WL1 may be in contact with a lower surface of the pixel circuit layer PCL. The lower surface of the pixel circuit layer PCL is referred to as a first pixel surface PCS.

That is, the pixel circuit layer PCL may have the first pixel surface PCS in a direction away from the light-emitting diode LED. The lower surface of the pixel circuit layer PCL and the lower surface of the terminal portion PAD may be located on the same plane. The first pixel surface PCS and the first terminal surface PAS may be located on the same plane.

The first connection line WL1 may be in contact with the first pixel surface PCS. A side surface of the first connection line WL1 and the lower surface of the first connection line WL1 may be surrounded by the first elastomer layer 400. As the first connection line WL1 has a structure embedded in the first elastomer layer 400, the first elastomer layer 400 may absorb stress that may be concentrated on the first connection line WL1 when the display panel 10 is stretched.

In addition, because the connection area 12 of the display panel 10 may be greatly transformed, the organic insulating layer OIL (refer to FIG. 6) may be located in the connection area 12 of the first elastomer layer 400 instead of the inorganic insulating layer IIL (refer to FIG. 6). For example, the sub-organic insulating layer 119, the first organic insulating layer 121, and the second organic insulating layer 123, which are located in the pixel area 11, may extend to the connection area 12.

The second connection line WL2 electrically connected to the pixel circuit PC and the terminal portion PAD may be located in the first terminal area PA1 of the display panel 10. The second connection line WL2 may be in direct contact with each of the lower surface of the pixel circuit layer PCL and the lower surface of the terminal portion PAD. That is, the second connection line WL2 may be in contact with each of the first pixel surface PCS and the first terminal surface PAS. A side surface of the second connection line WL2 and a lower surface of the second connection line WL2 may be surrounded by the first elastomer layer 400. As the second connection line WL2 has a structure embedded in the first elastomer layer 400, the first elastomer layer 400 may absorb stress that may be concentrated on the second connection line WL2 when the display panel 10 is stretched.

The first elastomer layer 400 may be located on each of the lower surface of the terminal portion PAD and the lower surface of the pixel circuit layer PCL to cover each of the first connection line WL1 and the second connection line WL2. The first elastomer layer 400 may be located on each of the first pixel surface PCS and the first terminal surface PAS to cover each of the first connection line WL1 and the second connection line WL2.

In addition, because the first terminal area PA1 of the display panel 10 may be greatly transformed, the organic insulating layer OIL (refer to FIG. 6) may be located in the first terminal area PA1 of the first elastomer layer 400 instead of the inorganic insulating layer IIL (refer to FIG. 6). For example, the sub-organic insulating layer 119, the first organic insulating layer 121, and the second organic insulating layer 123, which are located in the pixel area 11, may extend to the first terminal area PA1.

The second elastomer layer 300 may be located on the light-emitting diode LED, the terminal portion PAD, the first connection line WL1, and the second connection line WL2. The second elastomer layer 300 may absorb stress that may be transmitted to the light-emitting diode LED, the terminal portion PAD, the first connection line WL1, and the second connection line WL2 by covering the light-emitting diode LED, the terminal portion PAD, the first connection line WL1, and the second connection line WL2.

A printed circuit board 20 may face the first terminal surface PAS of the terminal portion PAD. The connection portion 30 may electrically connect the printed circuit board 20 to the first terminal surface PAS. The connection portion 30 may be in contact with each of the lower surface of the terminal portion PAD and an upper surface of the printed circuit board 20. Each of the printed circuit board 20 and the connection portion 30 may be in contact with the first elastomer layer 400. The first elastomer layer 400 may surround the connection portion 30.

For example, as shown in FIG. 9A, the first elastomer layer 400 may not cover the printed circuit board 20. The printed circuit board 20 may protrude from the first elastomer layer 400 in a direction away from the light-emitting diode LED (that is, a −z direction). A lower portion of the printed circuit board 20 may not be in contact with the first elastomer layer 400.

For example, as shown in FIG. 9C, the first elastomer layer 400 may cover the printed circuit board 20 (e.g., including a bottom surface of the printed circuit board 20). A portion of the printed circuit board 20, which overlaps the first elastomer layer 400, may be accommodated in the first elastomer layer 400. The portion of the printed circuit board 20, which overlaps the first elastomer layer 400, may not be exposed to the outside by the first elastomer layer 400.

However, this is an example, and a positional relationship between the first elastomer layer 400 and the printed circuit board 20 may vary according to required design factors, such as a thickness of each of the first elastomer layer 400 and the printed circuit board 20.

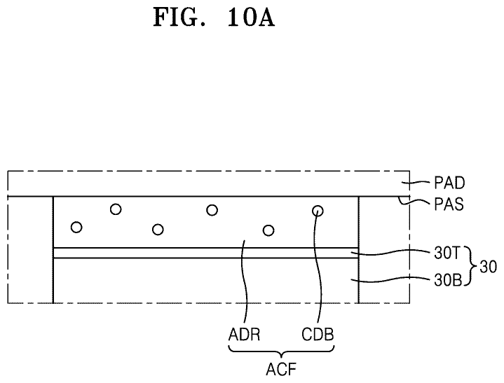

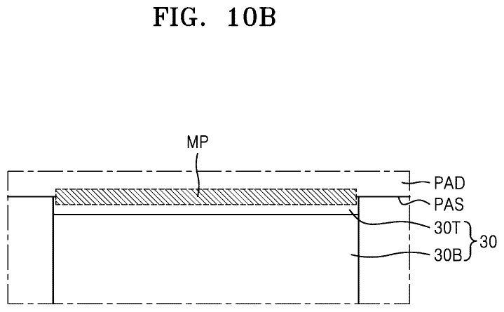

FIGS. 10A and 10B are schematic cross-sectional views of a portion of the terminal portion PAD and the connection portion 30, according to one or more embodiments.

Referring to FIG. 10A, the terminal portion PAD may be connected to the connection portion 30. The first terminal surface PAS of the terminal portion PAD may be connected to the connection portion 30. The connection portion 30 may include a circuit terminal 30T and a connection body portion 30B of the connection portion 30. A direct circuit may be located in the connection body portion 30B. In one or more embodiments, the terminal portion PAD may be electrically connected to the circuit terminal 30T of the connection portion 30 through an anisotropic conductive film ACF. For example, the terminal portion PAD may be physically and/or electrically connected to the circuit terminal 30T of the connection portion 30 through the anisotropic conductive film ACF, even if not in direct contact with the circuit terminal 30T of the connection portion 30.

The anisotropic conductive film ACF may include an adhesive resin ADR, and a plurality of conductive balls CDB distributed in the adhesive resin ADR. The adhesive resin ADR may fix the plurality of conductive balls CDB in a corresponding area, and may physically connect the terminal portion PAD to the connection portion 30. The plurality of conductive balls CDB may electrically connect the terminal portion PAD to the circuit terminal 30T of the connection portion 30.

In one or more other embodiments, the terminal portion PAD and the circuit terminal 30T of the connection portion 30 may be electrically connected to each other by a plurality of soldering units.

Referring to FIG. 10B, the terminal portion PAD may be directly connected to the connection portion 30. The first terminal surface PAS of the terminal portion PAD may be directly connected to the connection portion 30. In one or more embodiments, the terminal portion PAD may be electrically connected to the circuit terminal 30 T of the connection portion 30. For example, the terminal portion PAD may be electrically connected to the circuit terminal 30T of the connection portion 30 through a melting portion MP. The melting portion MP may be an alloy including a portion of the terminal portion PAD, and a portion of the circuit terminal 30T of the connection portion 30. The portion of the terminal portion PAD and the portion of the circuit terminal 30T of the connection portion 30 may be melted and bonded in the melting portion MP.

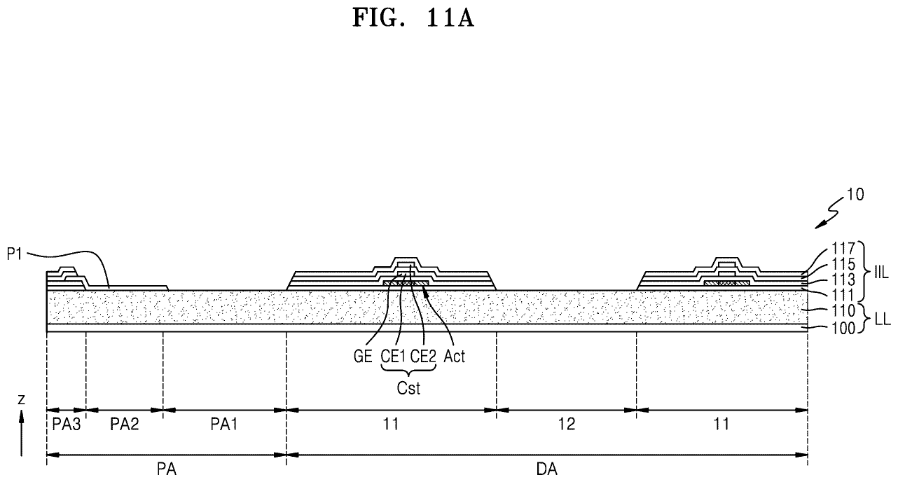

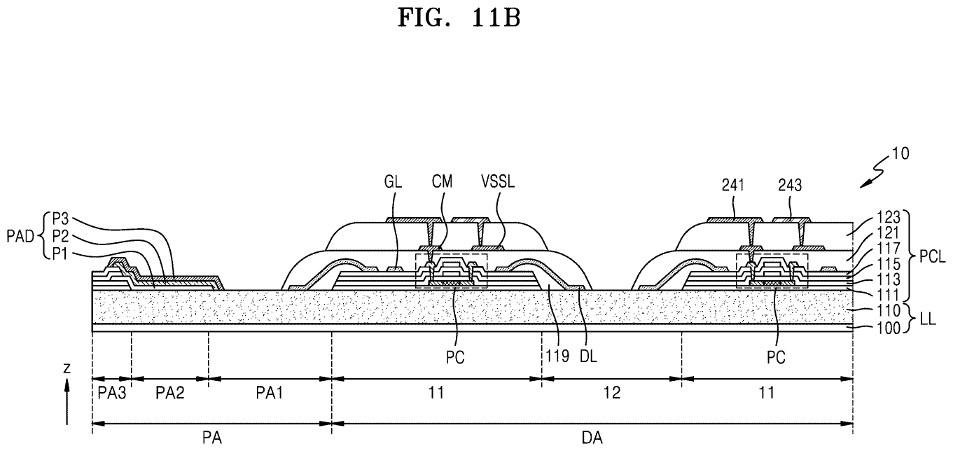

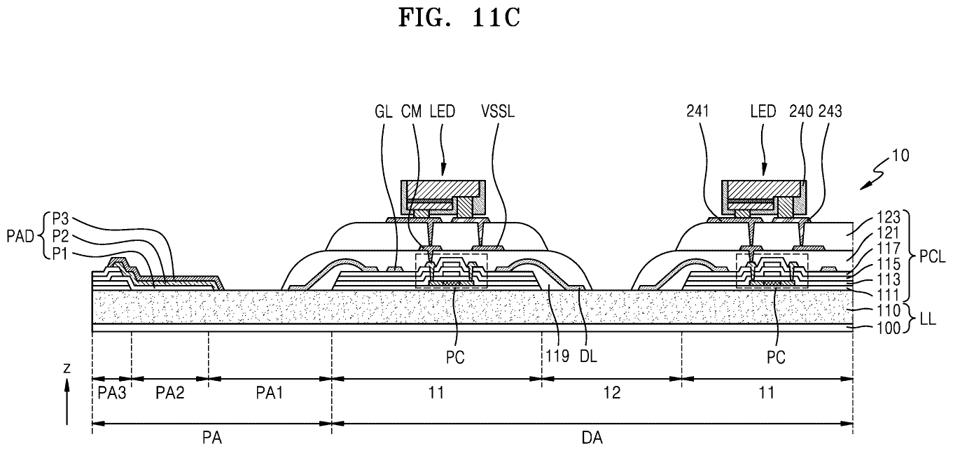

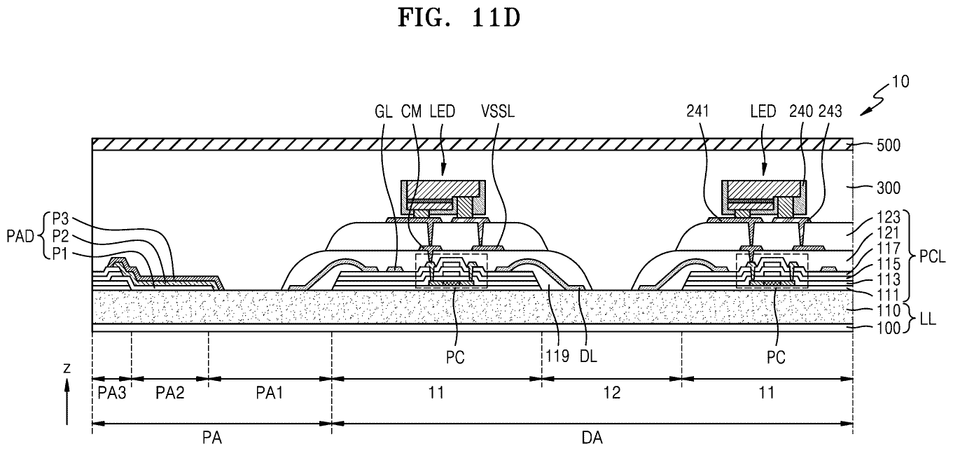

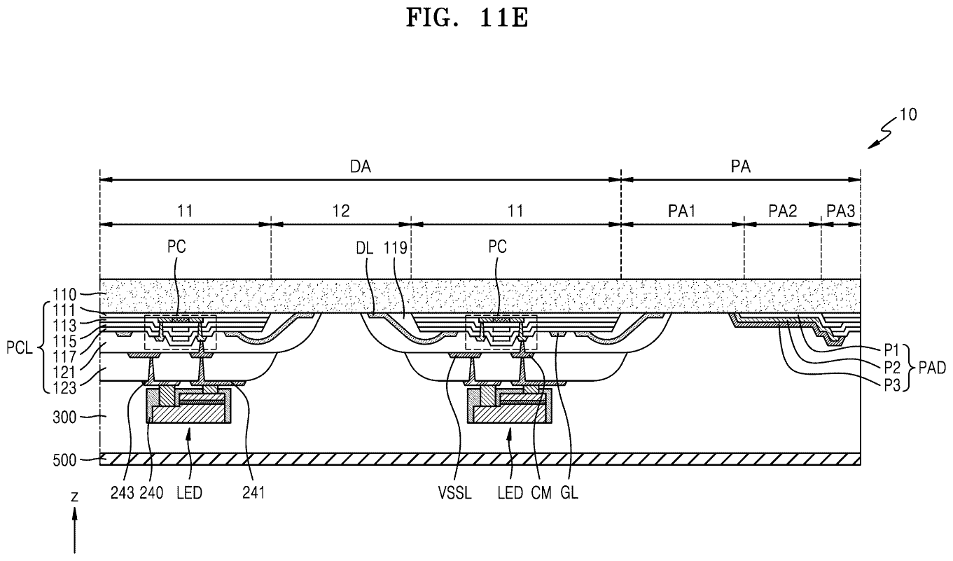

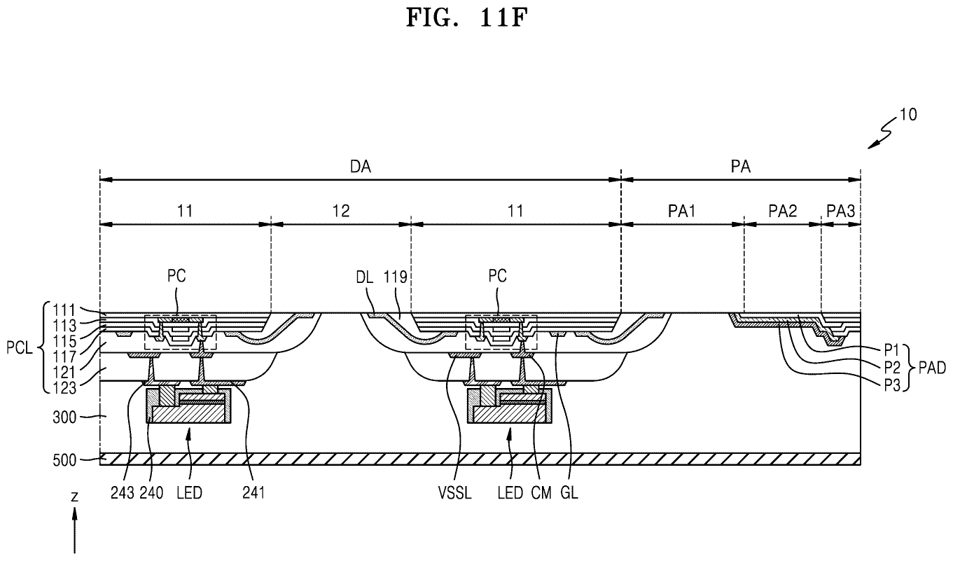

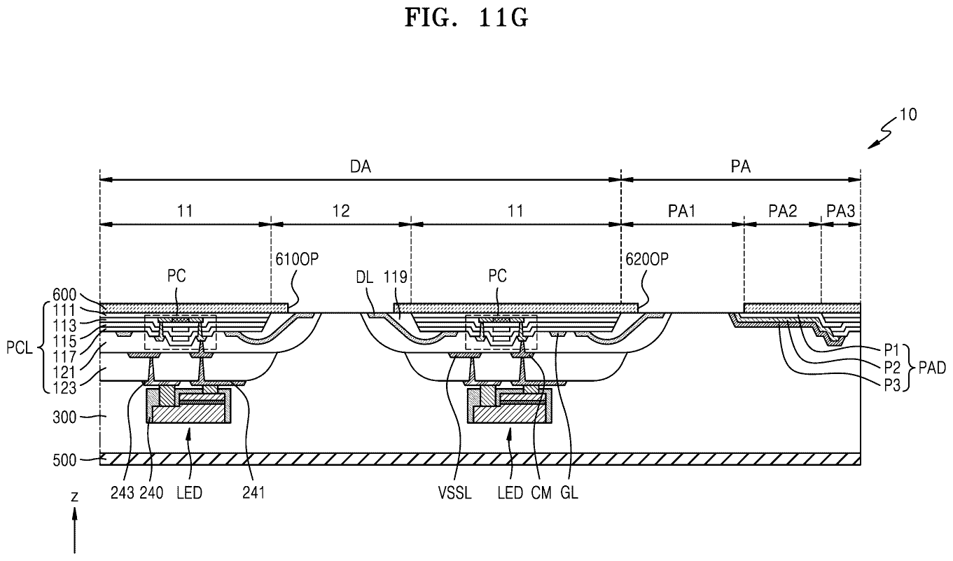

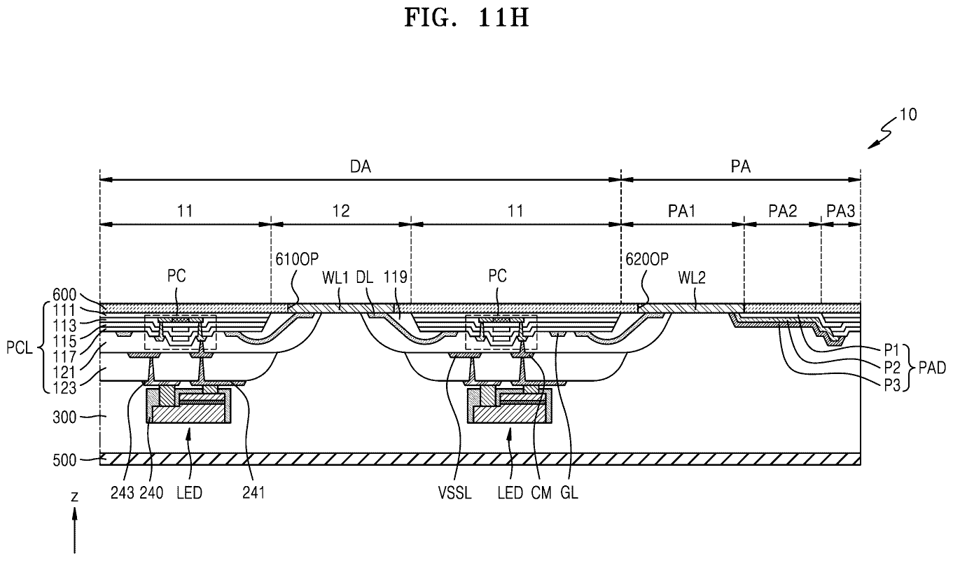

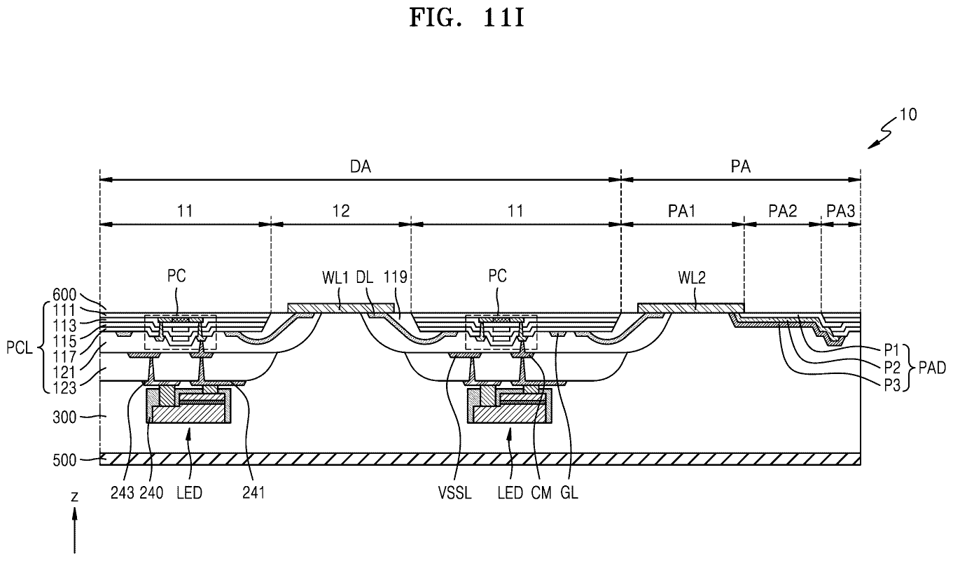

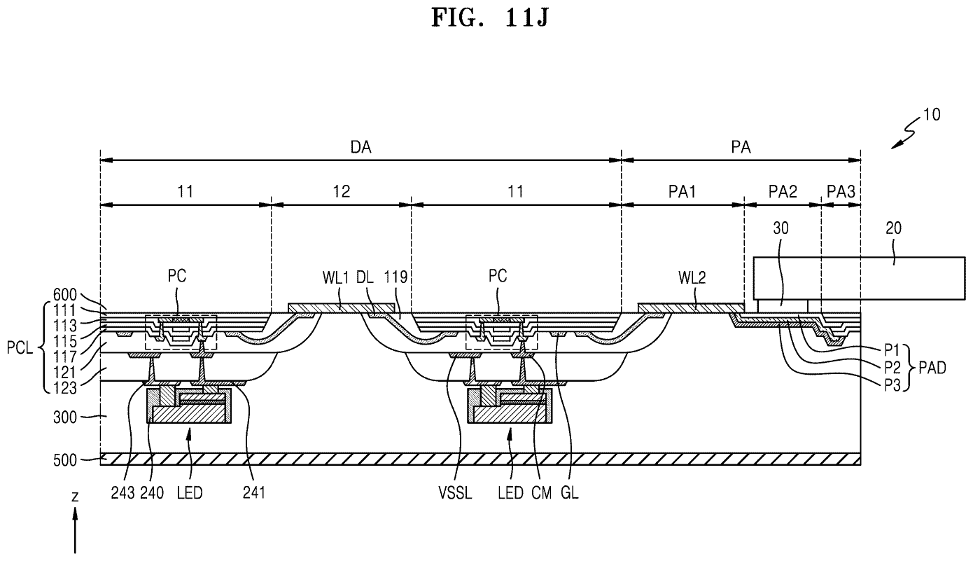

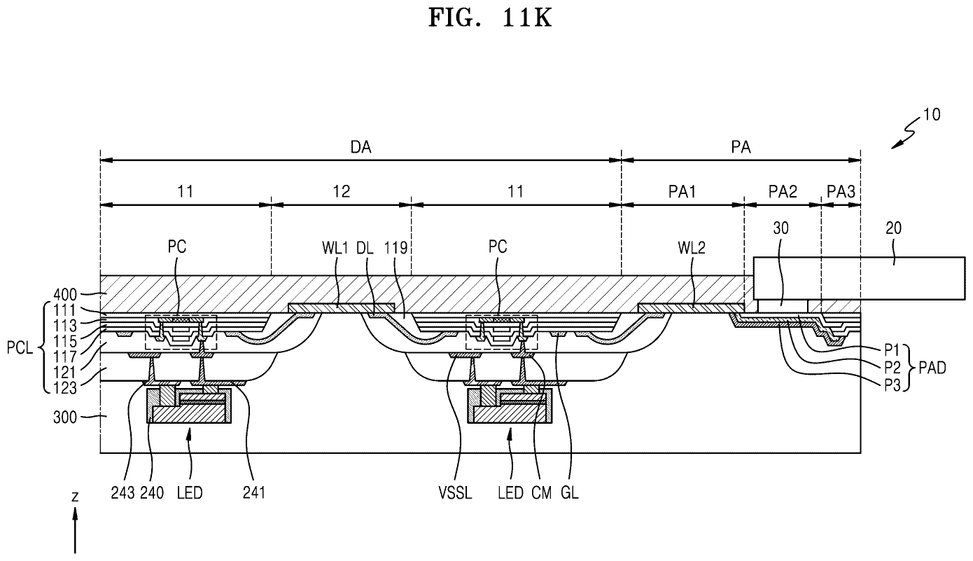

FIGS. 11A to 11K are cross-sectional views sequentially illustrating processes of a method of manufacturing the display panel 10 according to one or more embodiments.

In the description of the method of manufacturing the display panel 10 according to one or more embodiments, the description of the display panel 10 made with reference to FIG. 9A may be applied to the display panel 10.

Referring to FIGS. 11A to 11K, the same reference numerals as those in FIGS. 6 to 9A refer to the same members, and redundant descriptions thereof are omitted.

First, referring to FIG. 11A, a lower layer LL may be formed to form the display panel 10. The lower layer LL may be a layer temporarily located to form the display panel 10, which is stretchable. That is, the lower layer LL may support the pixel circuit layer PCL (refer to FIG. 6) while forming the pixel circuit layer PCL (refer to FIG. 6), but may be removed after the pixel circuit layer PCL (refer to FIG. 6) is formed.

In one or more embodiments, the lower layer LL may include the substrate 100, and a base layer 110 located on the substrate 100. The substrate 100 may be a rigid substrate. For example, the substrate 100 may be a transparent substrate containing SiO₂ as a main component, or a substrate including a polymer resin, such as reinforced plastic. The base layer 110 may include a polymer resin. For example, the base layer 110 may include polyethersulfone, polyacrylate, polyetherimide, polyethylene naphthalate, polyethylene terephthalate, polyphenylene sulfide, polyarylate, polyimide, polycarbonate, cellulose acetate propionate, or the like. In one or more embodiments, a thickness of the base layer 110 may be greater than a thickness of the substrate 100.

The inorganic insulating layer IIL and a portion the thin-film transistor TFT (refer to FIG. 9A) may be formed on the lower layer LL. For example, the buffer layer 111, the semiconductor layer Act, the gate-insulating layer 113, the gate electrode GE, the first interlayer insulating layer 115, the second electrode CE2, and the second interlayer insulating layer 117 may be sequentially stacked on the lower layer LL.

However, the inorganic insulating layer IIL may be located only in the pixel area 11 and the third terminal area PA3 and may not be located in the connection area 12, the first terminal area PA1, and the second terminal area PA2. For example, a portion of the inorganic insulating layer IIL, which overlaps the connection area 12, the first terminal area PA1, and the second terminal area PA2, may be removed through an etching process. In a process in which the gate electrode GE is formed in the pixel area 11, the first terminal layer P1 including the same material as the gate electrode GE may be formed in the terminal area PA. The first terminal layer P1 may be located within the first terminal area PA1 to be spaced apart from the pixel area 11.

Next, referring to FIG. 11B, the sub-organic insulating layer 119 may be formed on the second interlayer insulating layer 117. The sub-organic insulating layer 119 may be located in the pixel area 11, the connection area 12, and the first terminal area PA1. The sub-organic insulating layer 119 may cover a side surface of the inorganic insulating layer IIL from which a portion has been removed. The sub-organic insulating layer 119 may reduce or prevent the likelihood of disconnection of lines due to a step-difference between the inorganic insulating layer IIL and the lower layer LL. The source electrode SE (refer to FIG. 9A) and the drain electrode DE (refer to FIG. 9A) of the pixel circuit PC may be formed on the second interlayer insulating layer 117, and the data line DL may be formed on the second interlayer insulating layer 117 and the sub-organic insulating layer 119.

The first organic insulating layer 121 may be formed on the pixel circuit PC, and the connection electrode CM and the second voltage line VSSL may be formed on the first organic insulating layer 121. The second organic insulating layer 123 may be formed on the connection electrode CM, and the first electrode pad 241 and a second electrode pad 243 may be formed on the second organic insulating layer 123. In one or more embodiments, the first organic insulating layer 121 may be formed only in the pixel area 11, and the second organic insulating layer 123 may extend within the pixel area 11 to be partially formed in the connection area 12 and the terminal area PA. However, as shown in FIG. 11B, the second organic insulating layers 123, which are adjacently located, may be located within the connection area 12 to be spaced apart from each other.

In a process in which the source electrode SE (refer to FIG. 9A) and the drain electrode DE (refer to FIG. 9A) are formed in the pixel area 11, the second terminal layer P2 including the same material as the source electrode SE (refer to FIG. 9A) and the drain electrode DE (refer to FIG. 9A) may be formed in the terminal area PA. The second terminal layer P2 may be in (e.g., may terminate in) the first terminal area PA1 to be spaced apart from the pixel area 11.

In addition, in a process in which the connection electrode CM is formed in the pixel area 11, the third terminal layer P3 including the same material as the connection electrode CM may be formed in the terminal area PA. The third terminal layer P3 may be located within (e.g., may terminate in) the first terminal area PA1 to be spaced apart from the pixel area 11.

Next, referring to FIG. 11C, the light-emitting diode LED may be formed on the pixel circuit layer PCL. The light-emitting diode LED may be located in the pixel area 11. The light-emitting diode LED may be an inorganic light-emitting diode, as described above with reference to FIG. 8A. The light-emitting diode LED may be covered with the protective layer 240.

Then, referring to FIG. 11D, the second elastomer layer 300 may be formed to cover the light-emitting diode LED and the terminal area PA. The second elastomer layer 300 may include the same material as that described above with reference to FIG. 9A. The second elastomer layer 300 may absorb stress that may otherwise be transmitted to the light-emitting diode LED and the pixel circuit PC when the display panel 10 is stretched. In addition, the second elastomer layer 300 may planarize the display panel 10. The second elastomer layer 300 may be formed through a thermal curing process after a material forming the second elastomer layer 300 is deposited.

In the thermal curing process, the display panel 10 may be heated at 150° C. or higher for 30 minutes to 2 hours. However, the disclosure is not limited thereto, and the second elastomer layer 300 may also be cured through an ultraviolet (UV) curing process.

A carrier film 500 may also be formed on the second elastomer layer 300. In one or more embodiments, the carrier film 500 may be attached to an upper surface of the second elastomer layer 300 through an adhesive layer arranged between the second elastomer layer 300 and the carrier film 500. The carrier film 500 may be a protective film that may reduce or prevent scratches or marks occurring on the display panel 10 during the process. For example, the carrier film 500 may include an insulating film. However, this is an example, and a method of attaching the carrier film 500 may be varied.

Next, referring to FIGS. 11D and 11E, after the substrate 100 is detached from the lower layer LL, the display panel 10 may be inverted. For example, the substrate 100 may be removed from the base layer 110. A coupling force between the substrate 100 and the base layer 110 may be weakened by irradiating a laser to a surface of the substrate 100, which is opposite to one surface of the substrate 100 in contact with the base layer 110. Accordingly, the substrate 100 may be peeled off from the base layer 110. However, this is an example, and a method of removing the substrate 100 may be varied.

After the substrate 100 is detached, the display panel 10 may be inverted so that upper and lower surfaces thereof are inverted. For example, the display panel 10 may be inverted so that the carrier film 500 is located at a lower portion, and so that the base layer 110 is located at an upper portion.

Then, referring to FIG. 11F, in a state in which the display panel 10 is inverted, the base layer 110 may be removed. The base layer 110 may be entirely removed through a dry etching process. As the base layer 110 is removed, a lower surface of the pixel circuit layer PCL, and a lower surface of the terminal portion PAD may be exposed. Here, the lower surface of the pixel circuit layer PCL may be seen as an upper surface of the pixel circuit layer PCL because the display panel 10 is inverted. In addition, the lower surface of the terminal portion PAD may be seen as an upper surface of the terminal portion PAD because the display panel 10 is inverted.

Next, referring to FIG. 11G, in the state in which the display panel 10 is inverted, a sacrificial layer 600 may be formed on the lower surface of the pixel circuit layer PCL. The sacrificial layer 600 may be patterned to have a first opening 610OP overlapping the connection area 12, and a second opening 620OP overlapping the first terminal area PA1. In one or more embodiments, the sacrificial layer 600 may be formed through a dispensing process or an inkjet printing process. However, this is an example, and a method of forming the sacrificial layer 600 may be varied.

The sacrificial layer 600 may be a layer temporarily used to pattern the first connection line W1 (refer to FIG. 11H) and the second connection line WL2 (refer to FIG. 11H). In one or more embodiments, when each of the first connection line WL1 and the second connection line WL2 includes a liquid metal, the sacrificial layer 600 may include a liquid metal adhesion-inhibiting material. However, this is an example, and the sacrificial layer 600 may not be limited as long as the sacrificial layer 600 includes a hydrophobic material.

Then, referring to FIG. 11H, the first connection line WL1 may be formed within the first opening 610OP of the sacrificial layer 600. In addition, the second connection line WL2 may be formed within the second opening 620OP of the sacrificial layer 600.

In one or more embodiments, each of the first connection line WL1 and the second connection line WL2 may include a liquid metal, and a material forming each of the first connection line WL1 and the second connection line WL2 may be applied by using a roller, a stamp, or the like. However, it is difficult to achieve precise patterning when using a roller or a stamp, and thus, a material for forming the first connection line WL1 may be applied to an area surrounding the first opening 610OP, and a material for forming the second connection line WL2 may be applied to an area surrounding the second opening 620OP. At this time, when the sacrificial layer 600 includes a liquid metal adhesion-inhibiting material as described above, the material for forming each of the first connection line WL1 and the second connection line WL2 may not be located on the sacrificial layer 600, and may be located only within the first opening 610OP and the second opening 620OP. That is, the first connection line WL1 and the second connection line WL2 may be patterned through the openings of the sacrificial layer 600 including a hydrophobic material.

Then, referring to FIGS. 11H and 11I, the sacrificial layer 600 may be removed. The sacrificial layer 600 including a hydrophobic material, such as a liquid metal adhesion-inhibiting material, may be removed through a cleaning process using water. Accordingly, only the first connection line WL1 formed within the first opening 610OP and the second connection line WL2 formed within the second opening 620OP may remain on the lower surface of the display panel 10.

That is, according to the method of manufacturing the display panel 10 according to one or more embodiments, because the sacrificial layer 600 is completely removed while the first connection line WL1 and the second connection line WL2 may be precisely patterned, no material that may reduce the stretchability of the display panel 10 remains, and thus, the stretchability of the display panel 10 may be improved. When the sacrificial layer 600 including a hydrophobic material remains, a coupling force with an upper layer may be weakened. Accordingly, as the sacrificial layer 600 has been removed, the structural stability of the display panel 10 according to one or more embodiments may also secured.

Then, referring to FIG. 11J, the printed circuit board 20 may be electrically connected to the terminal portion PAD. The connection portion 30 may electrically connect the printed circuit board 20 to the terminal portion PAD. In the second terminal area PA2, the connection portion 30 and the printed circuit board 20 may be in contact with each other. In addition, in the second terminal area PA2, the connection portion 30 and the terminal portion PAD may be in contact with each other.

Then, referring to FIG. 11K, the first elastomer layer 400 may be formed on the lower surface of the pixel circuit layer PCL. The first elastomer layer 400 may cover the first connection line WL1 and the second connection line WL2. The first elastomer layer 400 may be in contact with each of the printed circuit board 20 and the connection portion 30. The first elastomer layer 400 may surround the connection portion 30.

The first elastomer layer 400 may include the same material as that described above with reference to FIG. 9A. The first elastomer layer 400 may seal the lower portion of the display panel 10, and may absorb stress that may occur when the display panel 10 is stretched.

After the first elastomer layer 400 is formed, the display panel 10 may be inverted again to have the structure of the display panel 10 as shown in FIG. 9A. Thereafter, the carrier film 500 (refer to FIG. 11J) attached to the upper surface of the display panel 10 may be removed. The carrier film 500 may be removed by using a peeling tape. However, this is an example, and a method of removing the carrier film 500 may be varied.

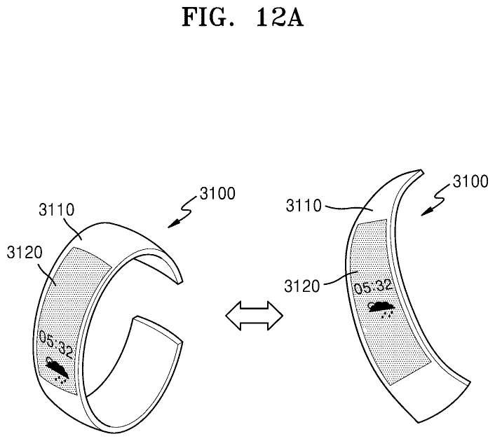

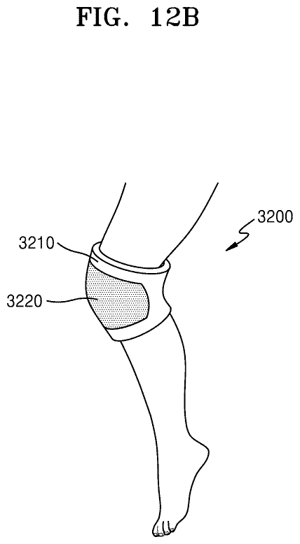

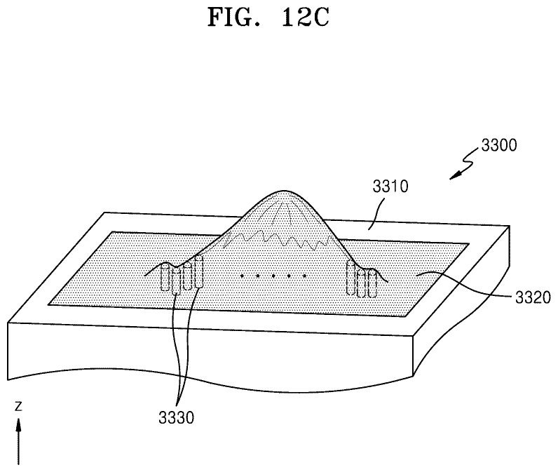

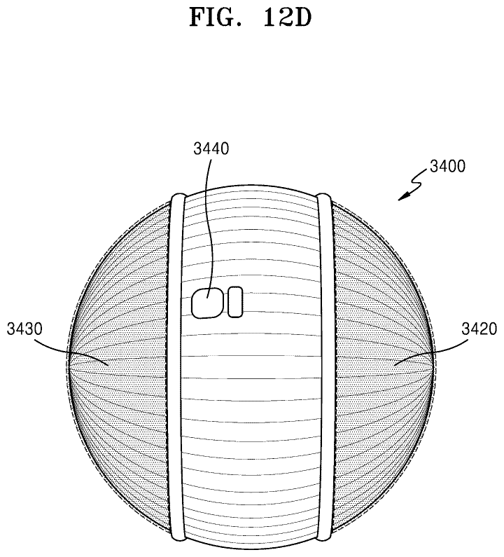

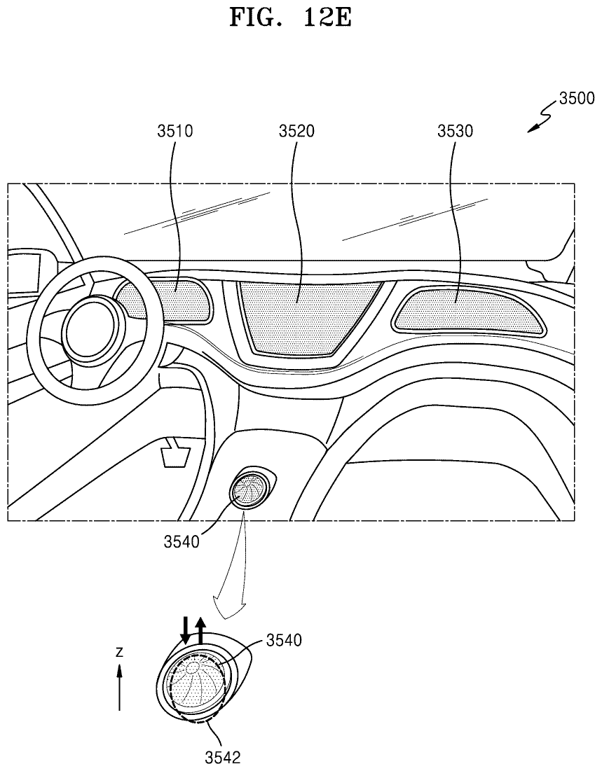

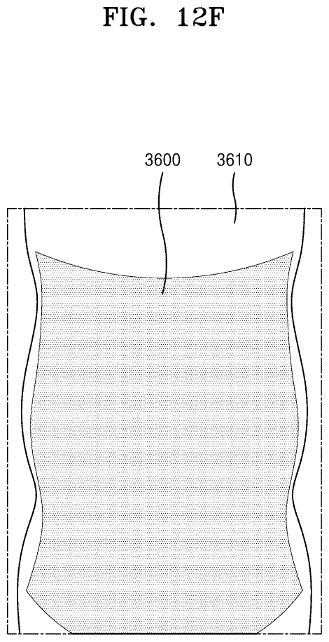

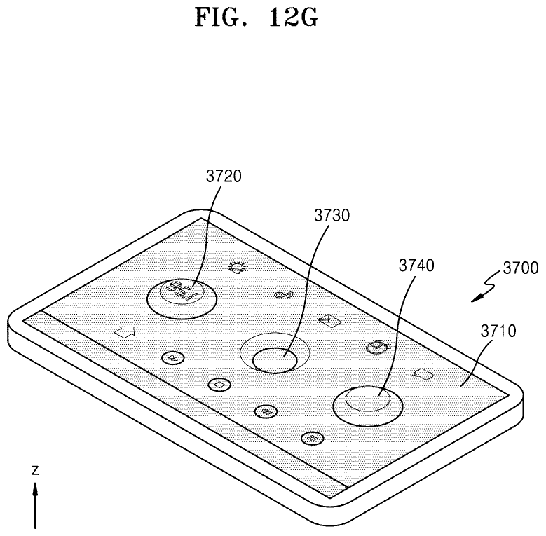

FIGS. 12A to 12G are schematic perspective views respectively showing embodiments of an electronic device including a display panel according to one or more embodiments.

Referring to FIG. 12A, a display panel according to one or more embodiments may be used as a wearable electronic device 3100 which may be worn on a part of a user's body. The wearable electronic device 3100 may include a body portion 3110, and a display portion 3120 provided in the body portion 3110. The display panel according to embodiments may be used as the display portion 3120 of the wearable electronic device 3100. As shown in FIG. 13A, the wearable electronic device 3100 may be transformable. In one or more embodiments, the wearable electronic device 3100 may be used as a smart watch or a smartphone depending on the user's choice.

FIG. 12B shows a medical electronic device 3200. In one or more embodiments, the medical electronic device 3200 may include a body portion 3210 and a light-emitting portion 3220. The display panel according to embodiments may be used as the light-emitting portion 3220 of the medical electronic device 3200. The light-emitting portion 3220 may emit light of a corresponding wavelength band (e.g., infrared light, visible light ray, or the like) to the body of a patient. In one or more embodiments, the body portion 3210 may include a stretchable fiber material, and may have a structure that the light-emitting portion 3220 may be worn on the user's body.

FIG. 12C shows an educational electronic device 3300. In one or more embodiments, the educational electronic device 3300 may include a display portion 3320 provided in a frame 3310. The display portion 3320 may use the display panel according to embodiments. The display portion 3320 may provide images, such as a sea with waves, a mountain covered with snow, or a volcano with flowing lava, and at this time, the display portion 3320 may extend in a height direction (e.g., a z direction) by reflecting the height of the waves, the mountain, or the volcano, for example. In some embodiments, a portion of the display portion 3320 may three-dimensionally show the movement of lava by sequentially changing the height along a direction in which the lava flows. The educational electronic device 3300 may include a plurality of pins (or stroke portions) 3330 arranged on the rear surface of the display portion 3320 so that the display portion 3320 may be stretched in the height direction. While the pins 3330 move along a third direction (e.g., a z direction or a −z direction), an image displayed on the display portion 3320 may be implemented to have a three-dimensional height. FIG. 12C shows the educational electronic device 3300, but the use is not limited as long as the device provides corresponding image information.

As shown in FIGS. 12A to 12C, an electronic device of which the shapes may be variable is described as the electronic device, but the disclosure is not limited thereto. As to be described below, the display panel according to embodiments may be used in an electronic device in which a portion capable of displaying images (e.g., a screen) is fixed.

FIG. 12D shows a robot 3400 as an electronic device according to one or more embodiments. The robot 3400 may recognize movement or objects by using a camera unit 3440, and may display corresponding images through display portions 3420 and 3430. In some embodiments, as described above, because the display panel according to one or more embodiments may be stretched in various directions, the display panel may be assembled into a body frame having a hemispherical shape, and accordingly, the robot 3400 may include the display portions 3420 and 3430 having hemispherical shapes.

FIG. 12E shows a vehicle display apparatus 3500 as an electronic device according to one or more embodiments. The vehicle display apparatus 3500 may include a cluster 3510, a center information display (CID) 3520, and/or a co-driver display 3530. Because the display panel may be stretched in various directions, the display panel may be used in the cluster 3510, the CID 3520, and/or the co-driver display 3530 regardless of the shape of the internal frame of the vehicle.

FIG. 12E shows that the cluster 3510, the CID 3520, and the co-driver display 3530 are separated from each other, but the disclosure is not limited thereto. In one or more other embodiments, two or more selected from the cluster 3510, the CID 3520, and the co-driver display 3530 may be integrally connected to each other.

In some embodiments, the vehicle display apparatus 3500 may include a button 3540 that may display a corresponding image. Referring to the enlarged view of FIG. 12E, the button 3540 having a hemispherical shape may include an object 3542 that provides the feeling of using while moving in the z direction or the-z direction, and a display device located on the object 3542. In some embodiments, when the object 3542 has a three-dimensionally rounded surface, the display device may also have a three-dimensionally rounded surface.

FIG. 12F shows that an electronic device according to one or more embodiments is an advertising or exhibiting electronic device 3600. In some embodiments, the advertising or exhibiting electronic device 3600 may be installed on a fixed structure 3610, such as a wall or pillar. When the structure 3610 includes an uneven surface as shown in FIG. 12F, the advertising or exhibiting electronic device 3600 may be arranged along the uneven surface of the structure 3610. In some embodiments, the advertising or exhibiting electronic device 3600 may be installed on the structure 3610 by using a heat shrink film or the like.

FIG. 12G shows that an electronic device according to one or more embodiments is a controller 3700. The controller 3700 may include an image-type button. For example, the controller 3700 may include first to third button areas 3720, 3730, and 3740 in which a partial area of a display portion 3710 protrudes in a z direction or a −z direction (e.g., is depressed in the z direction). In some embodiments, the first and third button areas 3720 and 3740 may protrude in the z direction, and the second button area 3730 may protrude in the −z direction (or may be depressed in the z direction).

According to some embodiments, a display apparatus having improved stretchability and implementing images with excellent quality, and an electronic device including the display apparatus may be provided. T effects described above are examples, and effects of the disclosure are not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display apparatus comprising:
a light-emitting diode;
a pixel circuit layer comprising a pixel circuit electrically connected to the light-emitting diode, and having a first pixel surface facing in a direction away from the light-emitting diode;
a first connection line contacting the first pixel surface of the pixel circuit layer, and electrically connected to the pixel circuit;
a terminal portion having a first terminal surface facing in the direction away from the light-emitting diode;
a second connection line contacting the first pixel surface of the pixel circuit layer and the first terminal surface of the terminal portion, and electrically connecting the pixel circuit to the terminal portion;
a printed circuit board comprising a driving circuit; and
a connection portion electrically connecting the printed circuit board to the first terminal surface of the terminal portion.

2. The display apparatus of claim 1, wherein the first pixel surface of the pixel circuit layer and the first terminal surface of the terminal portion are at a same plane.

3. The display apparatus of claim 1, further comprising a first elastomer layer below the first pixel surface of the pixel circuit layer and the first terminal surface of the terminal portion to overlap the first connection line and the second connection line.

4. The display apparatus of claim 3, wherein the printed circuit board contacts the first elastomer layer.

5. The display apparatus of claim 3, wherein the first elastomer layer surrounds the connection portion in plan view.

6. The display apparatus of claim 1, further comprising a second elastomer layer above the pixel circuit layer to cover the light-emitting diode.

7. The display apparatus of claim 1, wherein the pixel circuit comprises:
a semiconductor layer; and
a gate electrode overlapping the semiconductor layer, and
wherein the terminal portion comprises a first terminal layer having the first terminal surface, and comprising a same material as the gate electrode.

8. The display apparatus of claim 1, further comprising a signal line electrically connected to the pixel circuit, and contacting the first connection line.

9. The display apparatus of claim 8, wherein the signal line comprises a data line.

10. The display apparatus of claim 1, wherein the first connection line and the second connection line are stretchable.

11. An electronic device comprising a display panel having a terminal area, a pixel area, and a connection area, wherein the display panel comprises:
a pixel circuit layer in the pixel area, and comprising a pixel circuit;
a light-emitting diode above the pixel circuit layer, and electrically connected to the pixel circuit;
a first connection line in the connection area, contacting a lower surface of the pixel circuit layer, and electrically connected to the pixel circuit;
a terminal portion in the terminal area;
a second connection line contacting the lower surface of the pixel circuit layer and a lower surface of the terminal portion, and electrically connecting the pixel circuit to the terminal portion;
a printed circuit board comprising a driving circuit; and
a connection portion electrically connecting the terminal portion to the printed circuit board.

12. The electronic device of claim 11, wherein the terminal area, the pixel area, and the connection area are sequentially arranged in one direction.

13. The electronic device of claim 11, wherein the connection portion contacts the lower surface of the terminal portion and the lower surface of the pixel circuit layer.

14. The electronic device of claim 11, wherein the lower surface of the pixel circuit layer and the lower surface of the terminal portion are at a same plane.

15. The electronic device of claim 11, wherein the display panel further comprises a first elastomer layer below the lower surface of the terminal portion and the lower surface of the pixel circuit layer to overlap the first connection line and the second connection line.

16. The electronic device of claim 15, wherein the printed circuit board contacts the first elastomer layer.

17. The electronic device of claim 11, wherein the display panel further comprises a second elastomer layer above the pixel circuit layer to cover the light-emitting diode.

18. The electronic device of claim 11, wherein the display panel further comprises a signal line electrically connected to the pixel circuit and contacting the first connection line.

19. The electronic device of claim 18, wherein the signal line comprises a data line.

20. The electronic device of claim 11, wherein the first connection line and the second connection line are stretchable.
